(19) United States
(12) Patent Application Publication
(10) Pub. No.: US 2012/0228125 A1
(43) Pub. Date: Sep. 13, 2012

(54) CREATION OF MAGNETIC FIELD (VECTOR POTENTIAL) WELL FOR IMPROVED PLASMA DEPOSITION AND RESPUTTERING UNIFORMITY

(76) Inventors: Liqi Wu, Santa Clara, CA (US); Ishtak Karim, San Jose, CA (US); Huatan Qiu, Dublin, CA (US); Kie-Jin Park, San Jose, CA (US); Chunming Zhou, Milpitas, CA (US); Karthik Colinjivadi, San Jose, CA (US)

(21) Appl. No.: 13/425,646

(22) Filed: Mar. 21, 2012

Related U.S. Application Data
(63) Continuation-in-part of application No. 13/224,077, filed on Sep. 1, 2011.
(60) Provisional application No. 61/384,917, filed on Sep. 21, 2010.

(51) Int. Cl. C23C 14/35; C23C 14/34; C23C 14/14

(52) U.S. Cl. 204/192.15; 204/192.12; 204/298.02; 204/298.06; 204/298.16

(57) ABSTRACT

A physical vapor deposition (PVD) system includes N coaxial coils arranged in a first plane parallel to a substrate-supporting surface of a pedestal in a chamber of a PVD system and below the pedestal. M coaxial coils are arranged adjacent to the pedestal. Plasma is created in the chamber. A magnetic field well is created above a substrate by supplying N currents to the N coaxial coils, respectively, and M currents to the M coaxial coils, respectively. The N currents flow in a first direction in the N coaxial coils and the M second currents flow in a second direction in the M coaxial coils that is opposite to the first direction. A recessed feature on the substrate arranged on the pedestal is filled with a metal-containing material by PVD using at least one operation with high density plasma having a fractional ionization of metal greater than 30%.

### CROSS-REFERENCE TO RELATED APPLICATIONS

This application is a continuation in part of U.S. patent application Ser. No. 13/224,077, filed on Sep. 1, 2011, which claims the benefit of U.S. Provisional Application No. 61/384,917, filed on Sep. 21, 2010. The disclosures of the above applications are incorporated herein by reference in their entirety.

### FIELD

The present disclosure relates to ionized physical vapor deposition (PVD) systems and methods.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Ionized physical vapor deposition (PVD) in magnetron systems confines high density plasma in both a target region and a transfer region using balanced magnetic fields. The magnetic fields are generated by electromagnetic coils or permanent magnets, which are typically located around a periphery of a deposition chamber. The plasma in the target region is leaked and transferred through magnetic null points (where the field approximately vanishes) created in the vicinity of the target. The plasma escaping from narrow magnetic orifices forms a beam with a steep radial profile. Under certain conditions, a circular magnetic null is created to improve on-substrate and in-feature performance of a film.

A typical magnetron system with coaxial electromagnetic coil sets forms a magnetic field profile that has a non-zero magnetic field in a central region of the deposition chamber and an increasing magnetic field with increasing radius. The strong field at walls of the deposition chamber keeps the plasma away from the walls. However, the finite field in the central region prevents charged species from diffusing much. As a result, domed deposition and resputtering profiles may occur along with poor deposition uniformity across the substrate.

If the magnetic field is weakened enough around the central region to allow for charged species diffusion, the magnetic field near the chamber walls also typically decreases enough to become ineffective in confining the plasma. This leads to deposition flux with low ion content, which causes poor film quality, step coverage, and continuity on patterned features.

Some substrate fabrication methods involve deposition of metal into recessed features that are formed in one or more dielectric layers of a substrate. The deposited metal creates conductive paths that extend horizontally and vertically to connect active devices (such as transistors) in a desired pattern. As the demand for performance increases, the sizes of the features have decreased and the aspect ratios of the features have increased. The difficulty of depositing metal into these features without forming voids or other defects has become more difficult.

In some examples, copper may be used as the metal due to its low resistivity and high electromigration resistance. The use of physical vapor deposition (PVD) methods for metal gap fill using copper is somewhat limited for small features and high aspect ratios. As a result, Damascene processing is typically used when copper is the metallization metal. Copper fill is often accomplished by depositing a thin conformal copper seed layer using PVD and then deposition of bulk copper by electroplating.

The bulk copper step typically requires the substrate to be transferred from the PVD chamber (where the seed layer was deposited) to a copper electrofill apparatus where the recesses are filled. During this step, the partially fabricated substrate is exposed to ambient atmosphere and to wet chemistry during electrofill.

### SUMMARY

A method of operating a physical vapor deposition (PVD) system includes arranging N coaxial coils in a first plane parallel to a substrate-supporting surface of a pedestal in a chamber of a PVD system and below the pedestal; arranging M coaxial coils adjacent to the pedestal, where N and M are integers greater than zero; creating plasma in the chamber; creating a magnetic field well above a substrate by supplying N currents to the N coaxial coils, respectively, and M currents to the M coaxial coils, respectively, wherein the N currents flow in a first direction in the N coaxial coils and the M second currents flow in a second direction in the M coaxial coils that is opposite to the first direction; and filling a recessed feature on a substrate arranged on the pedestal with a metal-containing material by PVD using at least one operation with high density plasma having a fractional ionization of metal greater than 30%,

In other features, the recessed feature has a width of less than about 300 nm. The fractional ionization of metal is greater than 50%. The method further includes depositing a layer of the metal-containing material on the substrate and coating at least a bottom portion of the recessed feature and performing a plurality of profiling cycles. Each of the plurality of profiling cycles comprises a net etching operation removing a first portion of a material residing at the bottom of the recessed feature and a net deposition operation depositing a second portion of a material at the bottom of the recessed feature.

In other features, the net etching operation comprises redistributing the metal-containing material from the bottom portion of the recessed feature to sidewalls of the recessed feature in at least some of the plurality of profiling cycles. Performing the plurality of profiling cycles fills the recessed feature with the metal-containing material. Removing the first portion of a material residing at the bottom of the recessed feature comprises resputtering the material using high density plasma resputtering in at least some of the plurality of profiling cycles.

In other features, a deposited portion of the material is greater than an etched portion of the material for at least one of the profiling cycles. Performing the plurality of profiling cycles achieves net material deposition at the bottom portion of the recessed feature. The net etching operation comprises resputtering the material from the bottom of the recessed feature using high density plasma resputtering in at least some of the plurality of profiling cycles. The net etching operation reduces overhang material residing at an opening of the recessed feature during at least some of the profiling cycles.

In other features, the metal-containing material comprises copper. The substrate comprises a Damascene structure. The method includes performing a first profiling cycle having a first net etching operation followed by a second profiling cycle having a second net etching operation. The second net etching operation removes a larger fraction of deposited material than the first net etching operation.

In other features, the net deposition operation comprises applying an RF bias to the substrate. Arranging the M coaxial coils includes arranging the M coaxial coils in a second plane that is parallel to the surface of the pedestal and above the surface of the pedestal. Arranging the M coaxial coils includes arranging the M coaxial coils in a second plane that is parallel to the surface of the pedestal and below the surface of the pedestal. Arranging the M coaxial coils includes arranging at least some of the M coaxial coils in a second plane that is parallel to the surface of the pedestal and below the surface of the pedestal. The method include arranging remaining ones of the M coaxial coils in a third plane that is parallel to the surface of the pedestal and above the surface of the pedestal.

In other features, the magnetic field well is generally “U”-shaped and is centered on the substrate-supporting surface of the pedestal. A magnetic null is located inside the magnetic field well. A strong magnetic field is located outside of the magnetic field well.

In other features, at least one of the N coaxial coils has a first diameter, and at least one of the M coaxial coils has a second diameter, wherein the second diameter is greater than the first diameter. The PVD system includes a hollow cathode magnetron (HCM) target.

A physical vapor deposition (PVD) system comprises a target arranged in a target region of a chamber. A pedestal has a surface for supporting a substrate that is arranged in a substrate region of the chamber. A transfer region is located between the target region and the substrate region. N coaxial coils are arranged in a first plane parallel to the surface of the pedestal and below the pedestal. The PVD system include M coaxial coils, where N and M are integers greater than zero. N currents flow in a first direction in the N coaxial coils, respectively, and M currents flow in a second direction in the M coaxial coils that is opposite to the first direction, respectively. A controller comprises program instructions for creating plasma in the chamber, and filling a recessed feature on a substrate arranged on the pedestal with a metal-containing material by PVD using at least one operation with high density plasma having a fractional ionization of metal greater than 30%.

In other features, the recessed feature has a width of less than about 300 nm. The fractional ionization of metal is greater than 50%. The controller further comprises program instructions for depositing a layer of the metal-containing material on the substrate and coating at least a bottom portion of the recessed feature and performing a plurality of profiling cycles. Each of the plurality of profiling cycles comprises a net etching operation removing a first portion of a material residing at the bottom of the recessed feature and a net deposition operation depositing a second portion of a material at the bottom of the recessed feature.

In other features, the net etching operation comprises redistributing the metal-containing material from the bottom portion of the recessed feature to sidewalls of the recessed feature in at least some of the plurality of profiling cycles, performing the plurality of profiling cycles fills the recessed feature with the metal-containing material, and removing the first portion of a material residing at the bottom of the recessed feature comprises resputtering the material using high density plasma resputtering in at least some of the plurality of profiling cycles.

In other features, a deposited portion of the material is greater than an etched portion of the material for at least one of the profiling cycles. Performing the plurality of profiling cycles achieves net material deposition at the bottom portion of the recessed feature. The net etching operation comprises resputtering the material from the bottom of the recessed feature using high density plasma resputtering in at least some of the plurality of profiling cycles.

In still other features, the net etching operation reduces overhang material residing at an opening of the recessed feature during at least some of the profiling cycles. The metal-containing material comprises copper. The substrate comprises a Damascene structure.

In still other features, the controller further comprises program instructions for performing a first profiling cycle having a first net etching operation followed by a second profiling cycle having a second net etching operation. The second net etch operation removes a larger fraction of deposited material than the first net etch operation.

In other features, the net deposition operation comprises applying an RF bias to the substrate. The M coaxial coils are arranged in a second plane that is parallel to the surface of the pedestal and above the surface of the pedestal. The M coaxial coils are arranged in a second plane that is parallel to the surface of the pedestal and below the surface of the pedestal.

At least some of the M coaxial coils are arranged in a second plane that is parallel to the surface of the pedestal and below the surface of the pedestal and remaining ones of the M coaxial coils are arranged in a third plane that is parallel to the surface of the pedestal and above the surface of the pedestal.

In other features, the N coaxial coils and the M coaxial coils create a magnetic field well that is generally “U”-shaped and is centered on a substrate-supporting surface of the pedestal. A magnetic null is located inside the magnetic field well. A strong magnetic field is located outside of the magnetic field well. At least one of the N coaxial coils has a first diameter, and at least one of the M coaxial coils has a second diameter, wherein the second diameter is greater than the first diameter. The target includes a hollow cathode magnetron (HCM) target.

Further areas of applicability of the present disclosure will become apparent from the detailed description provided hereinafter. It should be understood that the detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIGS. 1-2 are cross-sectional views of physical vapor deposition (PVD) systems according to the present disclosure;

FIG. 3 includes a first graph showing magnetic confinement potential and a second graph showing plasma density;

FIG. 4 is a graph showing etch rate in normalized units (NU) as function of an inner diameter of the coaxial coils below a pedestal;

FIG. 5 is a graph showing deposition rate in NU as function of an inner diameter of the coaxial coils below the pedestal;

FIGS. 6 and 7 are plots showing simulated normalized magnetic field strengths and magnetic wells in the chamber with opposite polarities on the upper and lower coaxial coils;

FIG. 8 illustrates an etch rate profile;

FIGS. 9A-9F are cross-sectional views of a substrate during a dual Damascene processing;

FIGS. 10A-10B are cross-sectional views of a substrate during conventional PVD metal fill;

FIG. 11A-11C are cross-sectional views of substrates during high density plasma (HDP) metal fill according to the copy present disclosure;

FIG. 12 is a process flow diagram of an example method for HDP metal fill according to the copy present disclosure;

FIG. 13 is a process flow diagram of an example method for Atomic Layer Profiling (ALP) Metal Fill according to the present disclosure;

FIGS. 14A-14G are cross-sectional views of substrates during ALP metal fill;

FIG. 15 is a process flow diagram of an example method for ALP metal fill;

FIG. 16 is a cross-sectional view of an example of a substrate processing chamber according to the present disclosure;

FIG. 17 is a cross-sectional view of another example of a substrate processing chamber according to the present disclosure; and

FIG. 18 is a functional block diagram of a controller.

### DETAILED DESCRIPTION

The following description is merely illustrative in nature and is in no way intended to limit the disclosure, its application, or uses. For purposes of clarity, the same reference numbers will be used in the drawings to identify similar elements. As used herein, the phrase at least one of A, B, and C should be construed to mean a logical (A or B or C), using a non-exclusive logical OR. It should be understood that steps within a method may be executed in different order without altering the principles of the present disclosure.

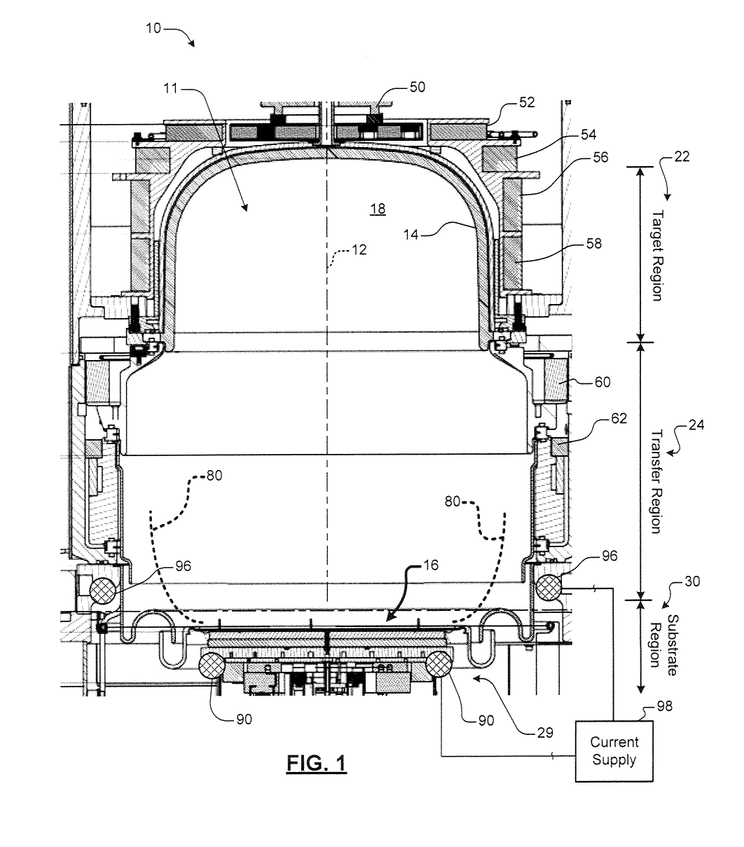

Referring now to FIG. 1, an exemplary PVD system is shown. As can be appreciated, while a Hollow Cathode Magnetron (HCM) PVD system 10 is shown, the present disclosure applies to other PVD systems. The HCM PVD system 10 includes a chamber 11, is generally symmetric about a central axis 12, and typically includes a cathode and an anode.

The cathode includes a target 14, which provides material to be deposited onto a substrate 16. For example only, the target 14 can be made of aluminum, tantalum, titanium, copper or other suitable target material. For HCM applications, the target 14 may have a hollow non-planar shape as shown, although other arrangements are contemplated.

Plasma is generated in the HCM PVD system 10 by introducing plasma feed gas, such as Argon, into a container portion 18 of the cathode. For example only, a negative bias may be applied to the cathode while holding the chamber at ground potential. For example only, a voltage supply (not shown) may supply a negative DC voltage across the target 14 and an adapter ring. The adapter ring and the chamber 11 may be connected to chassis ground or another reference potential. The anode is typically allowed to float. In other words, the anode is neither grounded nor biased. As a result, an electric field is generated across the plasma feed gas. For example only, the negative bias may be on the order of −90 VDC to −600 VDC, although other bias voltages may be used.

The negative bias on the cathode accelerates positive ions of the formed plasma towards the target 14 to sputter atoms from the target in a target region 22. The sputtered atoms may or may not become ionized, and a subset of them subsequently travels through a transfer region 24 and onto the substrate 16 arranged in a substrate region 30.

One or more permanent magnets 50 may be rotated relative to the central axis 12 to provide a rotating magnetic field in the target region of the chamber 11. Electromagnetic coils or permanent magnets may also be used to control the magnetic field at various points of the chamber 11. Since the substrate 16 is usually a circular substrate, coaxial electromagnetic coils or an array of permanent magnets may be used.

One or more electromagnetic coils or permanent magnets 52, 54, 56 and 58 are arranged in the target region 22 to control the magnetic field in the target region 22. Similarly, one or more electromagnetic coils or permanent magnets 60 and 62 are arranged in the transfer region 24 to control the magnetic field in the transfer region 24. Likewise, one or more electromagnetic coils (not shown) or permanent magnets are arranged in the substrate region 30 to control the magnetic field in the substrate region 30.

According to the present disclosure, a magnetic field (potential) well 80 is created in the vicinity of the substrate 16 using N first and M second coaxial coils 90 and 96, respectively. The magnetic field well 80 is defined by a region that has an approximately zero magnetic field surrounded by a region having a very strong magnetic field. Charged species can move fairly freely inside the magnetic field well 80 but cannot easily escape.

Creating the magnetic field well 80 with an appropriate diameter (approximately equal to a diameter of the substrate 16) near the substrate 16 allows the ions to distribute freely over the substrate 16 while being confined to the volume spanned by the substrate diameter.

To create the magnetic field well 80, N first coaxial coils 90 with N first coaxial coil diameters are arranged below the substrate 16 in the substrate region 30, where N is an integer greater than zero. M second coaxial coils 96 with M second coaxial coil diameters are arranged above the substrate 16 in the target region 22, where M is an integer greater than zero. The N first coaxial coil diameters can be the same or different. The M second coaxial coil diameters can be the same or different.

In a first example, the diameters of the N first coaxial coils 90 are less than the diameters of the M second coaxial coils 96. For example only, diameters of the N first coaxial coils 90 may be approximately 8-12 inches and diameters of the M second coaxial coils 96 may be 16-30 inches, although other dimensions may be used. In another example, the N first coaxial coils 90 may have a diameter approximately equal to a diameter of the substrate 16 and the M second coaxial coils 96 may have a diameter that is T times the diameter of the substrate 16, where T is greater than or equal to 1.

A current supply 98 supplies N currents that flow in a first direction in each of the N first coaxial coils 90, respectively. The current supply 98 supplies M currents that flow in a second direction in each of the M second coaxial coils 96, respectively. The first direction is opposite to the second direction. In some examples, the sum of the magnetic fields generated by the N first coaxial coils is opposite to the sum of the magnetic fields generated by the M second coaxial coils. In other examples, when N or M are greater than one, the additional coils can be arranged radially outside of each other in the same plane or axially on top of each other.

When the N currents flow in opposite directions in the N first coaxial coils 90 with respect to the M currents flowing in the M second coaxial coils 96, the magnetic fields cancel inside the N first coaxial coil diameters and add outside of the N first coaxial coil diameters. With appropriate diameters and current magnitudes, the magnetic field well 80 can be created. The well radius can be adjusted by varying current magnitudes and the coaxial coil diameters.

Magnitudes of the M currents may be adjusted relative to magnitudes of the N currents. For example only, a smallest one of the M currents may be approximately two times a greatest one of the N currents. In addition, the N currents supplied to the N first coaxial coils may have the same or different current values. Likewise, the M currents supplied to the M second coaxial coils may have the same or different current values. For example only, the first and second coaxial coils 90, 96 may be spaced approximately the same distance below and above the substrate 16, respectively. In one example, the N first coaxial coils 90 and the M second coaxial coils 96 are arranged 0-6 inches below and above the substrate 16, respectively.

The creation of the magnetic field well 80 in the vicinity the substrate 16 results in a high density uniform plasma over the surface of the substrate 16, which leads to high quality uniform film deposition. The N first coaxial coils 90 below the substrate 16 and the M second coaxial coils 96 above the substrate 16 run opposite currents with respect to each other. By modulating the strength and dimension of the magnetic field well 80, uniform deposition and resputtering profiles can be achieved.

For example only, the PVD system 10 may deposit a tantalum/tantalum nitride (Ta/TaN) barrier film (upon which a copper (Cu) seed layer is deposited). The electroplated Cu is generally deposited on the seed layer using a different tool. The step coverage and uniformity of the barrier layer are improved.

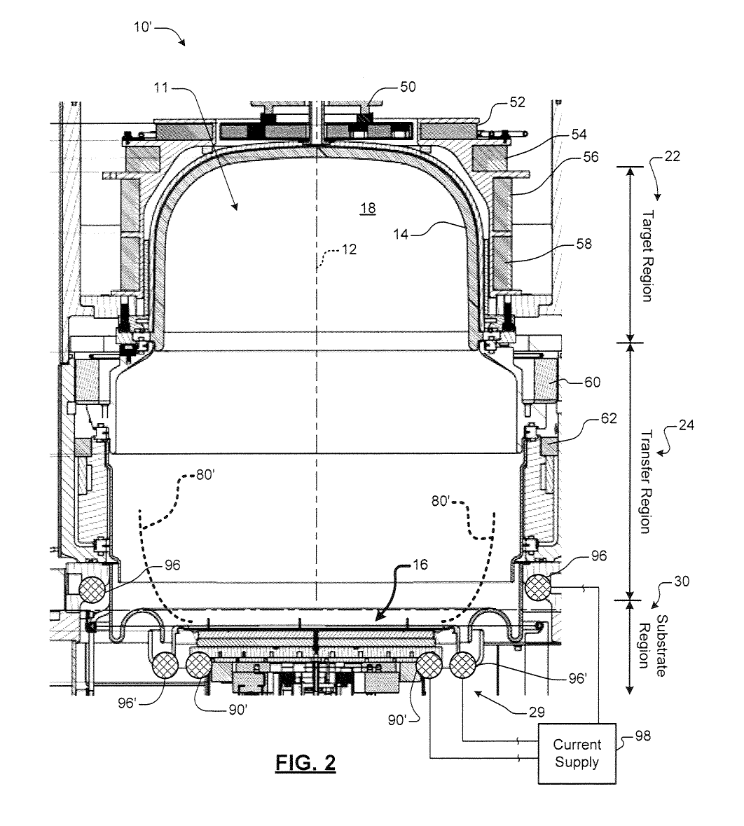

Referring now to FIG. 2, a PVD system 10′ is shown. As can be appreciated, N first coaxial coils 90′ and M second coaxial coils 96 and 96′ can be arranged in other locations relative to the substrate 16. For example in FIG. 2, the N first coaxial coils 90′ and one or more of the M second coaxial coils 96′ can be located in one or more planes below the substrate 16. If used, the remaining ones of the M second coaxial coils 96 may be located in a plane above the substrate as shown in FIG. 1. In other examples, all of the M second coaxial coils are arranged below the substrate.

When the N currents flow in opposite directions in the N first coaxial coils 90′ with respect to the M currents flowing in the M second coaxial coils 96 and 96′, the magnetic fields cancel inside the coil diameters and add outside of the coil diameters. With appropriate diameters and current magnitudes, the magnetic field well 80′ can be created. The radius of the magnetic field well 80′ can be adjusted by varying current magnitudes, coil position, and the first and second coaxial coil diameters.

For example, the N first and some of the M second coaxial coils 90′ and 96′ can be arranged approximately 0″-6″ below the substrate. In one example, the N first and some of the M second coaxial coils 90′ and 96′ can be arranged approximately 1″ below the substrate, the inner and outer diameters of the N first coaxial coils 90′ can be 12″/12.7″, respectively, and the inner and outer diameters of the M second coaxial coils 96′ can be 13.7″/14.7″, respectively, although other values may be used. As used herein, approximately refers to +/−0.25″. The remaining ones of the M second coaxial coils 96 may be arranged above the substrate as described above.

The N first coaxial coils 90′ and the M second coaxial coils 96′ run opposite currents with respect to each other. With the magnetic field generated by other coils or magnets (such as electromagnetic coils or permanent magnets 52, 54, 56, 58, 60 and/or 62), a magnetic potential well that is larger than the substrate size can be formed to facilitate plasma distribution.

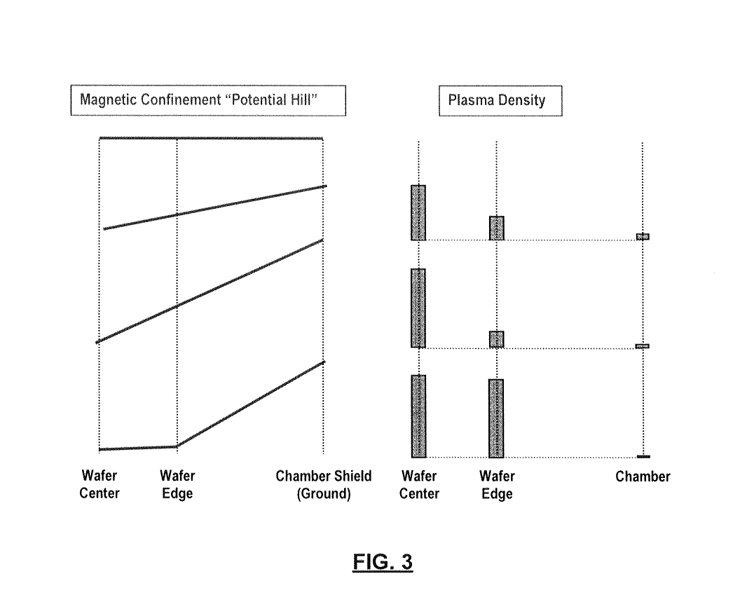

Referring now to FIG. 3, a cross-sectional view of the chamber 11, a first graph illustrating magnetic confinement potential and a second graph illustrating plasma density are shown. A controllable potential hill may be created using the N first and M second coaxial coils 90 and 96 (or 90′ and 96, 96′). A shape of the potential hill may be adjusted by varying magnitudes of current flowing through the M second coaxial coils 96 or 96′ and/or the N first coaxial coils 90 or 90′, a ratio of current flowing through the M second coaxial coils 96 or 96′ relative the N first coaxial coils 90 or 90′, the diameters of the N first coaxial coils 90 and/or the M second coaxial coils 96 (or 90′ and 96, 96′), and/or a ratio of the diameters of the N first coaxial coils 90 and the M second coaxial coils 96 (or 90′ and 96, 96′). The potential hill may be relatively constant across the substrate 16, or may have a constant or variable slope as desired.

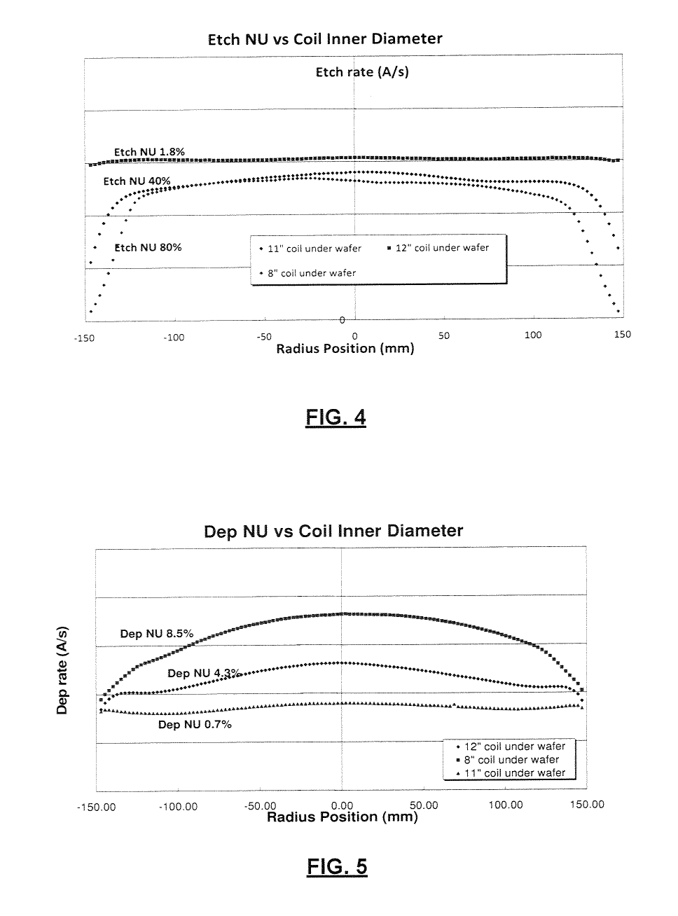

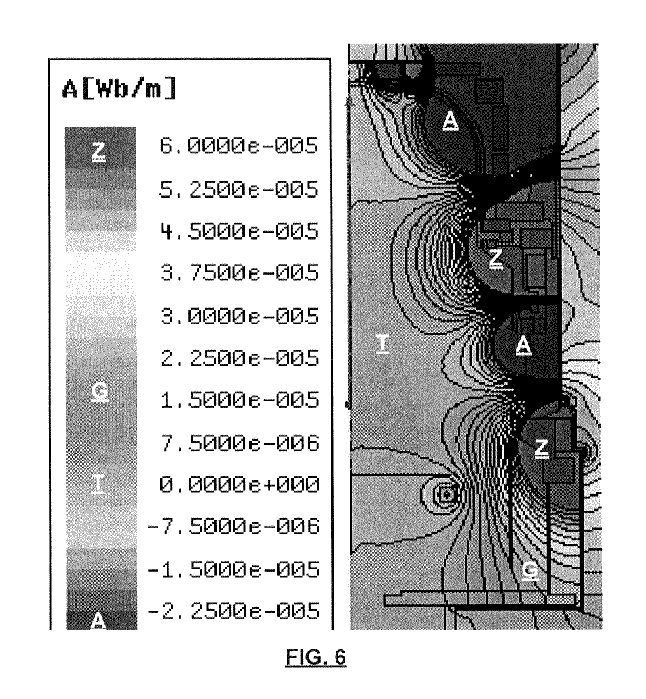

Referring now to FIGS. 4 and 5, more uniform etch and deposition rates are provided when the coaxial coil arrangement described above is used. In FIG. 4, etch rate in normalized units (NU) is shown as function of the diameter of the N first coaxial coils 90. In FIG. 5, deposition rate in NU is shown as function of the diameter of the N first coaxial coils 90. Improved deposition and etch symmetry across the substrate 16 is realized.

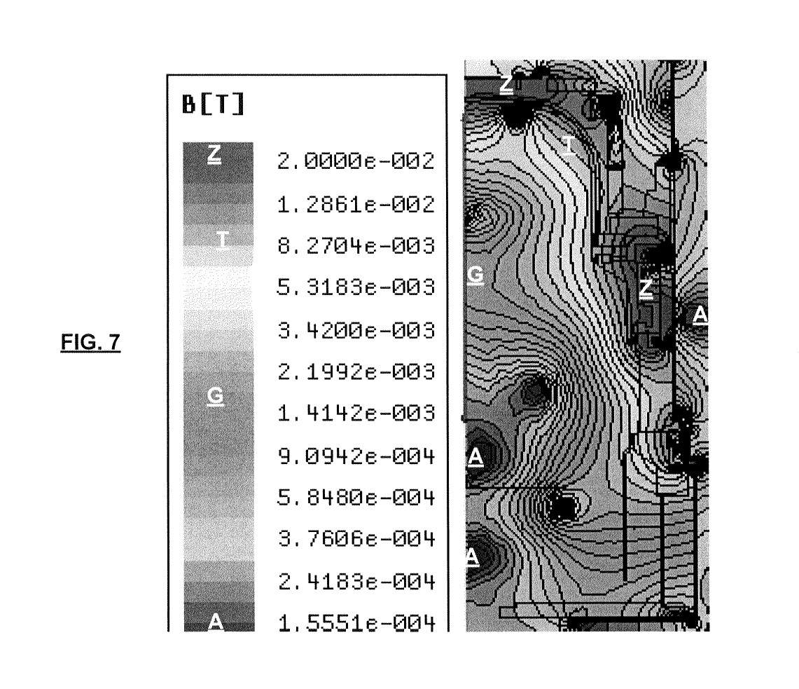

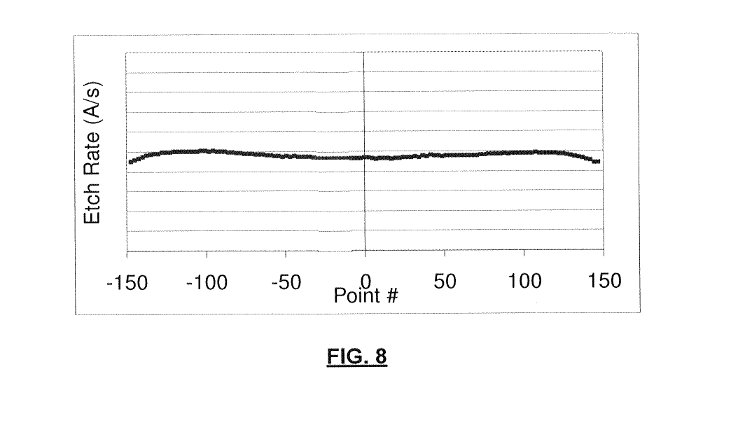

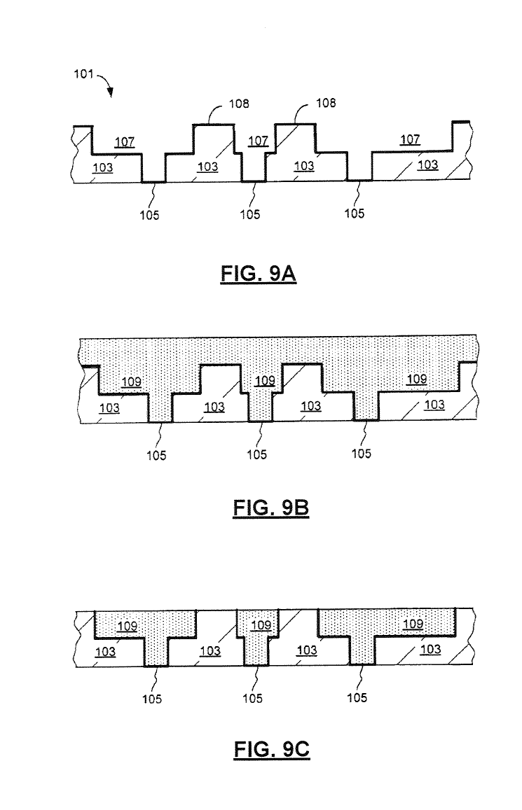

Referring now to FIGS. 6-8, another etch back process example is shown. In FIGS. 6 and 7, simulation plots show magnetic field strength and a magnetic well in the chamber with opposite electromagnetic coaxial coil polarities, respectively. In FIG. 8, an etch rate profile is shown. In this example, two circular nulls are created by alternating the polarity of the N first coaxial coils 90 and the M second coaxial coils 96. As the two null regions are close to each other, a magnetic field well 120 is formed. The substrate 16 is arranged close to a bottom of the magnetic field well 120. The magnetic strength simulation mapping in FIG. 6 shows a relative position of the magnetic field well 120 and the substrate 16. Within the near-zero magnetic field well 120, charged species are relatively free from the influence of a magnetic field, which results in excellent ion uniformity for resputtering applications. In FIG. 8, a line scan of etch rate profile across the substrate 16 is shown, which has excellent resputtering non-uniformity with 1-sigma standard deviation <3%.

### PVD Metal Fill Applications

In the following description, the N first coaxial coils and the M second coaxial coils are added to a PVD system to create a magnetic potential well in a PVD processing chamber. In some examples, the PVD system can perform PVD metal fill into small recesses of a substrate, such as recessing having a width that is less than 300 nm. The PVD system performs at least one operation using high density plasma having a fractional ionization of metal that is greater than 30%.

Creating the magnetic well in the processing chamber provides improved ion uniformity. As a result, the PVD system provides more uniform ion reflow capability across the substrate. The magnetic well also confines plasma on the substrate, which enhances the ion fraction and ion reflow capability and reduces damage to the substrate.

The systems and methods described herein can be used for depositing a variety of metals including (but are not limited to) copper, aluminum, titanium, silver, tantalum, tungsten and molybdenum. The systems and methods can be also used for partially or completely filling the recessed features with metal alloys, such as copper alloys and aluminum alloys. For example, alloys of copper or aluminum may be used to improve electromigration performance of IC devices (e.g., Cu—Ti alloy). Further, some alloys may be deposited directly onto a dielectric layer to create diffusion barrier layers. For example, alloys of copper with magnesium or with manganese can provide self-forming diffusion barrier layers due to oxidation of Mg or Mn on the surface of dielectric. In general, a variety of alloys may be deposited using described methods, including but not limited to Cu—Mg, Cu—Mn, Cu—Al, Al—Si, etc.

The systems and methods described herein may be used for partially or completely filling different types of recessed features, such as trenches, vias, and contact holes. The systems and methods enable metal fill by PVD, specifically by plasma PVD (ionized PVD or iPVD). Unlike conventionally used electrofill methods, PVD metal fill can be performed without exposing the substrate to an ambient atmosphere or to wet chemistry.

The described systems and methods typically do not require pre-deposition of seed layers prior to PVD fill of the recessed features. Further, in some examples, the systems and methods are capable of filling the recessed features with metal while simultaneously removing material (such as diffusion barrier material) from the field region of the substrate. In this case, the need for a separate planarization operation, which may be performed after the recessed features are filled, can be eliminated.

In some examples, annealing may be performed. In other examples, the PVD-deposited metal is self-annealed during deposition. A self-annealed metal has a microstructure characterized by large grain size, which provides high conductivity and high electromigration resistance. The microstructure of electrodeposited metal may be changed from a small-grain to a large-grain by a separate annealing operation. In some PVD-based filling methods described herein, the annealing operation may not be required since the PVD-deposited metal is already deposited in a large-grain form.

As background, a brief description of a copper dual Damascene process is set forth below. As can be appreciated, the systems and methods described below are not limited to dual Damascene processes and can be used in other processing methods. While the systems and methods described below can be used with substrates having relatively narrow recessed features with widths of about 300 nm and less, the systems and methods can be used to fill wider recesses.

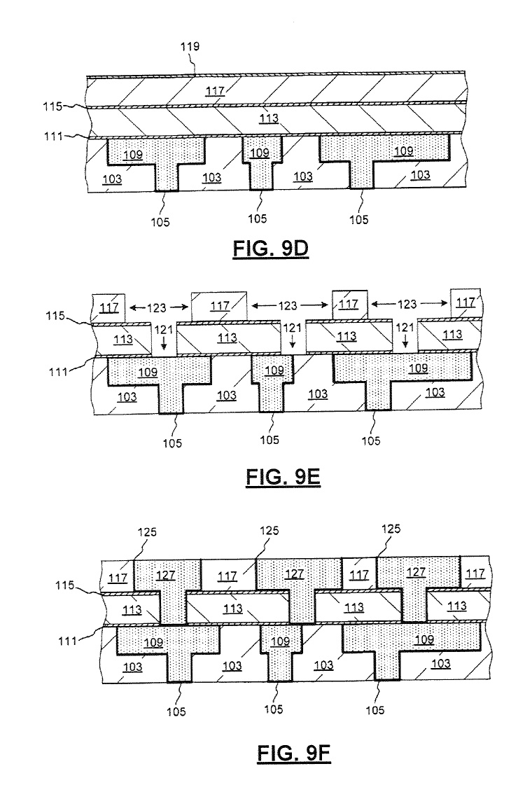

Referring now to FIGS. 9A-9E, substrates at various stages of the dual Damascene process are shown. In FIG. 9A, an example of a substrate 101 used for the dual Damascene process is illustrated. The substrate 101 may reside on one or more underlying layers including active devices such as transistors, a metallization layer including copper lines, or on any other layers.

Substrate 101 includes a dielectric layer 103 with etched line paths 107 (such as trenches and vias) and a field region 108. A diffusion barrier layer 105 coats an exposed surface of the substrate 101 both in the recesses and the field region 108. The diffusion barrier layer 105 protects the dielectric layer 103 and underlying active devices from diffusion of copper ions. Suitable diffusion barrier materials include tantalum, tantalum nitride, titanium nitride, titanium tungsten, and the like.

The barrier layer 105 may be created using physical vapor deposition (PVD), atomic layer deposition (ALD) or chemical vapor deposition (CVD). After the barrier layer 105 has been deposited, the recessed features 107 are filled with copper, which involves depositing a thin conformal copper seed layer onto the barrier layer 105 and electrodeposition of bulk copper. The bulk copper step typically requires the substrate to be transferred from the PVD chamber (where the seed layer was deposited) to a copper electrofill apparatus where the recesses 107 are filled. During this step, the partially fabricated substrate is exposed to ambient atmosphere and to wet chemistry during electrofill. In general, it would be preferable to minimize substrate transfers during fabrication. Further, exposure of the substrate to moisture and oxygen should be minimized.

In contrast, direct PVD copper fill methods offer advantages over the seed layer/electrofill process. Specifically, direct PVD copper fill can be performed in a dry vacuum environment without exposing the substrate to ambient atmosphere. Further, with direct PVD copper fill, deposition of the seed layer is not required. Thus, the vias and trenches may be filled with copper immediately after the copper diffusion barrier layer 105 has been deposited.

Despite these advantages, development of copper PVD fill methods to fill recessed features having widths that are less than about 300 nm has been difficult. Only wide, low aspect ratio recesses are filled with conventional iPVD. Conventional PVD (including iPVD) tends to deposit more material onto the field region than at bottom portions of the recessed feature. As a result, the material deposited onto the field tends to form overhangs at the recess openings. The overhangs lead to pinch-off and to formation of voids.

The present disclosure describes iPVD methods that minimize overhang and allow direct PVD fill of recessed features with widths of less than about 300 nm, less than about 200 nm, and even less than about 100 nm. Recessed features with aspect ratios of greater than 2:1 and even 5:1 can be filled. As a result, PVD copper fill can be successfully integrated into Damascene process.

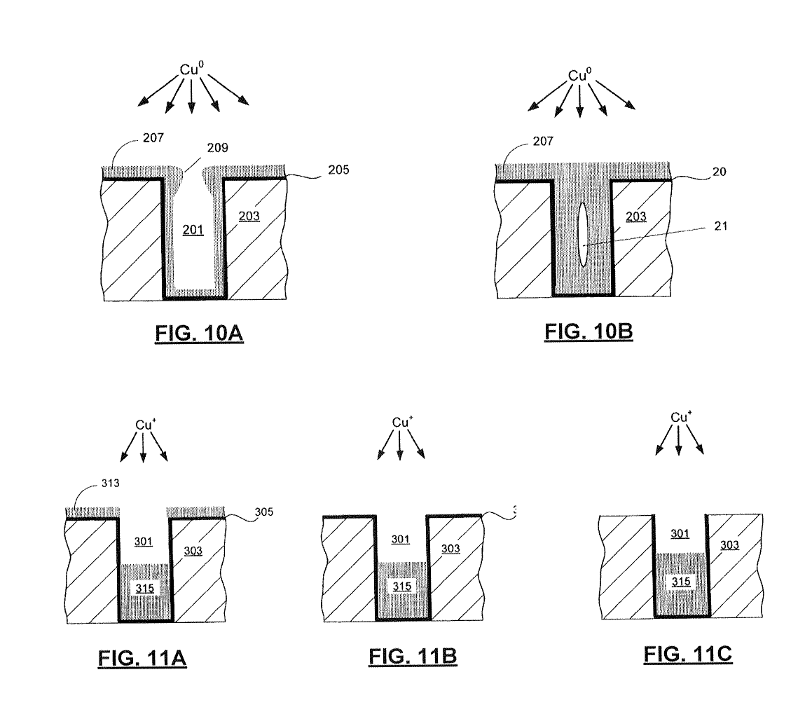

Referring now to FIG. 10A, the direct PVD fill methods, in one example, are performed such that copper is deposited both within the recessed features 107 and on the field region 108. A copper layer 109 is deposited into the features with an overburden, which resides on top of diffusion barrier layer 105 both over the field and over the filled recesses. All conductive material residing on the field (which includes both copper overburden and diffusion barrier residing on the field) is subsequently removed from the field region to prevent shorting between adjacent interconnects. This may be accomplished by a planarization operation, such as chemical mechanical polishing (CMP). Referring now to FIG. 9C, the diffusion barrier 105 and copper overburden have been removed from the field region and the dielectric layer 103 is exposed.

In some examples of HDP metal fill, it is possible to process the substrate from FIG. 9A to FIG. 9C without copper overburden in FIG. 9B. In this example, PVD plasma conditions are adjusted such that copper is deposited within the recesses 107 while the diffusion barrier layer is simultaneously removed from the field region as a result of plasma etching (resputtering). In this example, formation of copper overburden is avoided and undesired diffusion barrier material is removed from the field. When performed correctly, this approach requires little or no CMP.

After the copper layer 109 has been deposited, annealing may be performed to improve the microstructure of the copper by enhancing the copper grain size. Alternately, plasma deposition conditions may be adjusted such that copper is deposited with a desirable large-grain microstructure, and the annealing operation may not need to be performed.

In FIG. 9D, a diffusion barrier layer 111 is deposited to encapsulate the copper layer 109. Next, a first dielectric layer 113 of a dual Damascene dielectric structure is deposited on the diffusion barrier layer 111. The dielectric 113 is typically a low-k dielectric. An etch-stop layer 115 is deposited on the first dielectric layer 113. A second dielectric layer 117 of the dual Damascene dielectric structure is deposited in a similar manner to the first dielectric layer 113, onto the etch-stop layer 115. Then, an antireflective layer 119 may be deposited.

The dual Damascene process continues, as depicted in FIGS. 9E-9F, with etching of vias and trenches in the first and second dielectric layers. Vias 121 are etched through the antireflective layer 119 and the second dielectric layer 117. Standard lithography techniques are used to etch a pattern of these vias. The etching of the vias 121 is controlled such that the etch-stop layer 115 is not penetrated. As depicted in FIG. 9E, in a subsequent lithography process, the antireflective layer 119 is removed and trenches 123 are etched in the second dielectric layer 117; the vias 121 are propagated through the etch-stop layer 115, the first dielectric layer 113, and the diffusion barrier 111.

Next, as depicted in FIG. 9F, the vias and trenches are coated with a diffusion barrier 125 and are subsequently filled with copper using PVD fill methods described herein. When copper fill is performed with overburden, the structure is then planarized to remove the copper overburden and portions of diffusion barrier material 125 residing in the field region. Alternatively, PVD fill methods can simultaneously fill the recesses with copper while removing diffusion barrier material from the field region. The completed dual Damascene structure is shown in FIG. 9F, where PVD-deposited copper inlay 127 resides within dielectric and is separated from the dielectric layers 113 and 117 by a diffusion barrier layer 125. Copper routes 127 and 109 are in electrical contact and form conductive pathways, as they are separated only by diffusion barrier 125, which is also somewhat conductive. Three interconnects are shown in FIG. 9F.

Two examples of direct PVD fill methods will be now described in detail. Both examples can be implemented in a PVD chamber configured for generation of plasma. One example makes use of high density plasma (HDP) metal fill. In the second example, the recessed features are filled using atomic layer profiling (ALP) metal fill, which includes a plurality cycles each including an etching operation and a depositing operation. To provide a context for PVD metal fill, a brief overview of PVD and resputter (sputter etch) is set forth below.

A substrate is placed into a PVD processing chamber configured for plasma generation. The processing chamber includes a target. The target is connected to a negative DC bias and serves as a source of metal flux during deposition. A pedestal holds the substrate in position during material processing and may provide temperature control of the substrate. An inlet introduces an inert gas. One or more magnets confine the plasma in the proximity of the target. The system may also include the N first coaxial coils and the M second coaxial coils to create a magnetic potential well in the PVD processing chamber.

An RF bias can be optionally applied to the pedestal and substrate. When net deposition of material is desired, typically no RF bias or only a small RF bias is applied to the substrate. Inert gas (such as Argon) is introduced into the chamber and plasma is ignited by applying DC power to the target and confining the plasma with the magnetic field and the magnetic potential well. The inert gas is positively ionized in the plasma and forms ions (such as Ar⁺) that impinge on a negatively charged target with a sufficient momentum to dislodge metal atoms from the target. The neutral metal atoms can be further ionized in the plasma. The metal species including neutral and ionized metal are sputtered from the target onto the substrate and deposited on the surface of the substrate.

The positively charged inert gas ions and metal ions, under certain conditions, may acquire enough energy to impinge upon the substrate with a sufficient momentum to dislodge material from the substrate surface causing etching (resputter). Atoms of the etched material may be permanently removed from the substrate, or may be redistributed from one position on the substrate to a different position. For example, material may be redistributed from the bottom of the via to the via sidewalls.

Typically, etching and depositing occur simultaneously in the PVD chamber. Etching is performed by the inert gas ions and in some cases by metal ions impinging on the substrate with a sufficient momentum to dislodge the exposed material. Deposition is effected by neutral metal atoms and in some cases by metal ions being sputtered onto the substrate from the target. When an intrinsic etch rate E is greater than the intrinsic deposition rate D, a net etching process is occurring on the substrate. When the etch rate E is smaller than the deposition rate D, the process is characterized as a net deposition.

An etch rate to deposition rate ratio is often used to characterize the resputtering and deposition processes. At the E/D ratio of 1, no net deposition or etching is occurring. At the E/D ratio of 0, the process is entirely depositing. At E/D ratios of greater than 1 etching predominates. The E/D ratio is not necessarily the same in different features of the substrate. For example, the E/D ratio in the field, in the trench, and in the via may have different values. For example, it is possible to have net deposition in the field region (E/D<1) and net etch at the via bottom (E/D>1), which is characteristic of conventional iPVD. In HDP metal fill according to the present disclosure, net deposition occurs at the trench bottom (E/D<1) and net etch on the field (E/D>1). The resputtering process in general can be described as a process that provides an E/D>1 at least at one location on the substrate, e.g., at a via bottom, at a lowest lying feature on the substrate or in some cases in the feature having the highest aspect ratio. The fact that a net deposition is occurring at a different location on the substrate, e.g., in the field, does not change the fact that resputtering is performed.

An E/D ratio can be adjusted by modulating the process parameters, such as the DC power applied to the target and the RF power applied to the substrate. The intrinsic deposition rate D is typically increased as the DC power to the target increases, because larger amounts of metal species are sputtered from the target. An intrinsic etch rate E is typically increased as the RF power at the substrate increases, since it results in higher energy of inert gas ions and/or metal ions impinging on the substrate. Therefore the E/D ratio can be increased by increasing the RF(substrate)/DC(target) power ratio. In HOP metal fill, the intrinsic etch and deposition rates may be balanced by modulating plasma density (e.g., through modulation of magnetic field strength and magnetic potential well strength) and ion energy (e.g., by modulating RF power applied to the substrate).

In a PVD or iPVD system, metal deposition is accomplished primarily by neutral metal atoms, which are sputtered from the negatively biased metal target after the target is bombarded with inert gas ions. For example, Ar⁺ ions impinging on a copper target will cause sputtering of neutral copper atoms from the target onto the substrate disposed below the target. While copper atoms sputtered from the target may be subsequently ionized in plasma in the proximity of the target, a majority of them will return back to the target following the electrical field in that area. Metal ions that escape the electrical field typically lose their charge through the charge exchange collisions with the gas atoms and do not reach the proximity of the substrate. Therefore, in a conventional system the substrate typically experiences a flux of metal characterized by a relatively low fractional ionization. Fractional ionization of metal as used herein refers to a ratio of ionized metal to the total number of metal species (neutral metal atoms and ions) in the proximity of the substrate (e.g., within about 5 mm of the substrate). In a conventional iPVD system fractional ionization of metal typically does not exceed 30%. The metal flux experienced by the substrate in a conventional iPVD has little directionality due to a large fraction of non-directional neutral metal atoms.

Referring now to FIGS. 10A and 10B, deposition of copper in a conventional iPVD system is illustrated. In FIG. 10A, a trench 201 is formed in a layer of dielectric 203 and is lined with a layer of diffusion barrier material 205. A flux of copper mostly including neutral copper atoms is sputtered onto the substrate from the target. Because neutral copper atoms exhibit a wide angle distribution when they arrive at the substrate surface, a larger amount of copper is deposited onto the field region than onto the trench bottom. As a result, overhangs 209 are created at the opening of the trench long before the trench is filled with copper. In FIG. 10B, the structure resulting from an attempted PVD copper fill by conventional iPVD is shown. When large amounts of copper are deposited, the overhangs 209 close at the top of the feature before the feature is filled. Such pinch-off results in a structure having a void 211 within the copper-filled trench.

Because of this behavior, conventional PVD was not a suitable method for metal fill in relatively narrow recessed features. Further, conventional PVD inherently deposits larger amounts of material in higher-lying features (e.g., on the field region) as compared to the lower lying features (e.g., trench bottoms and via bottoms).

As it will be shown, PVD can be successfully used for metal fill in recessed features with widths of less than about 300 nm by using either the HDP metal fill or ALP metal fill approaches. Further, HOP metal fill can deposit metal within the recessed features at a higher rate than on the field region. HDP metal fill can deposit metal within the recessed features while simultaneously removing material from the field region.

### HDP Metal Fill

Recessed features may be filled with metal without forming substantial overhangs (e.g., overhangs resulting in pinch-off) by using a high density plasma for deposition. The HDP metal fill systems and methods use plasma characterized by high fractional ionization of metal in the proximity of the substrate. Suitable ionization levels include plasmas with fractional ionization of metal of at least about 30%. In other examples, the fractional ionization of metal of at least about 50% is used. In still other examples, fractional ionization of metal of at least about 80% is used. In yet other examples, fractional ionization of metal of at least about 99% is used. The fractional ionization may be measured in the proximity of the substrate. In some examples, the fractional ionization is measured within about 5 mm from the substrate.

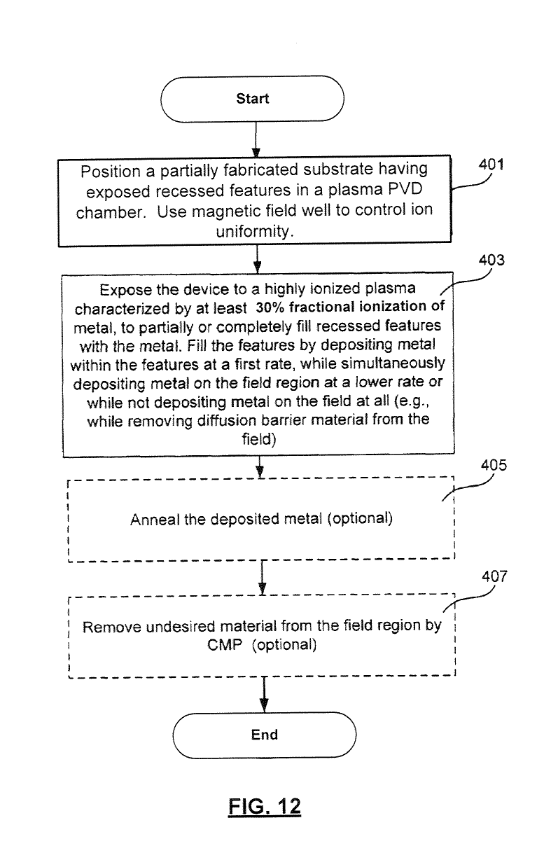

Plasma characterized by high fractional metal ionization shows an opposite deposition selectivity from a conventionally used plasma that is rich in neutral metal atoms. Depending on particular plasma parameters, PVD metal fill with high density plasma may be conducted according to the following examples in FIGS. 11A-11C.

Referring now to FIG. 11A, metal is deposited both within the recessed features and on the field, such that the net deposition rate at the feature bottom is greater than the net deposition rate on the field. In FIG. 11A, a trench 301 is formed in a layer of dielectric 303 and lined with a layer of diffusion barrier material 305. A flux of copper including positively charged copper ions is sputtered onto the substrate from a copper target.

Unlike neutral copper atoms, ionized copper has a narrower angle distribution with a large fraction of ions arriving at approximately a 90 degree angle relative to the substrate, which improves bottom coverage and reduces overhang. The distribution of the copper atoms can be further improved by the magnetic potential well. Further, copper ions have high mobility, and may migrate on the substrate surface until they arrive to the point of lowest energy, typically at the recess bottom. Further, copper ions may have sufficient energy to serve as plasma etching species as they impinge onto the substrate and resputter (etch) material from the substrate. Therefore, copper may be simultaneously deposited and etched from the substrate, with a certain E/D ratio.

In FIG. 11A, the E/D ratio is less than 1 both on the field and at the recess bottom. In other words, net copper deposition occurs at both surfaces. However due to the factors mentioned above, deposition on the field is slower than in the recess, that is the E/D at the trench bottom is smaller than in the field. Therefore, the trench may be filled before substantial overhangs are formed at the trench openings. A partially filled trench with a layer of copper 313 resides on the field region and a layer of copper 315 resides on the trench bottom.

Referring now to FIG. 11B, metal is deposited within the recessed feature while no net deposition or etching occurs in the field region. Copper fill 315 resides within the trench, while no copper overburden is formed on the field region. The diffusion barrier layer 203 remains exposed. In this case, the E/D ratio is less than 1 at the trench bottom, and is about 1 in the field region.

Referring now to FIG. 110, metal is deposited within the recessed feature while material is simultaneously removed (net etched) from the field region. The trench 301 is partially filled with copper layer 315, while diffusion barrier material is completely removed from the field exposing the dielectric layer 307. In this case, the E/D ratio is less than one at the trench bottom but is greater than one in the field region.

The systems and methods disclosed herein can be used to completely or partially fill the recessed features. In some examples at least about 20% of the recessed feature volume is filled from the bottom up. In other examples, at least about 80% of recess volume is filled, or the entire feature is completely filled with metal. In some examples the features are partially filled, e.g., to at least about 80% by volume, and the substrate is then subsequently planarized (e.g., by CMP) to remove any unwanted diffusion barrier and dielectric to a position that makes the level of the dielectric field substantially coplanar with the level of metal fill.

The metal fill is possible with the use of high density plasma characterized by high fractional ionization of metal due to high mobility of metal ions, high directionality of metal flux, and an etching component that removes material from the field region. In some examples, mobility of copper ions may be further increased by using high substrate temperature. However, increased substrate temperature is not required. In general, any substrate temperature in the range of between about −50° C. and 400° C. can be used. For example, the substrate temperature can be approximately −40° C.

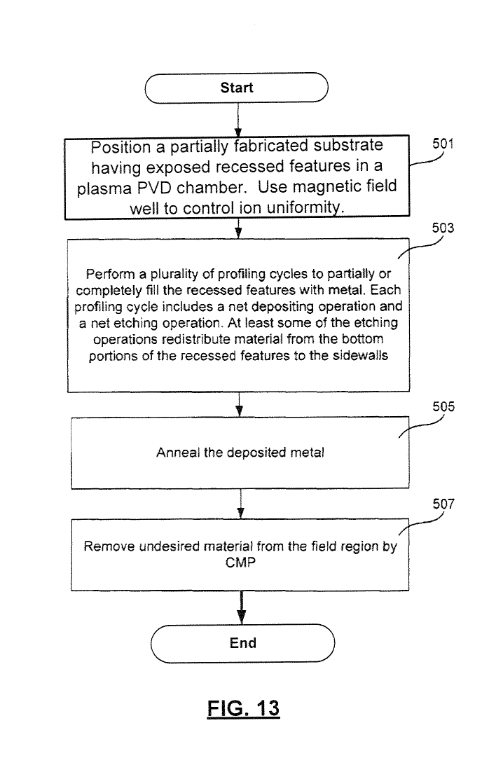

Referring now to FIG. 12, an example of a method for HDP metal fill is shown. The process starts at 401 where a partially fabricated device is positioned within the plasma PVD chamber. The PVD apparatus may include a magnetron capable of generating strong magnetic field and confining plasma. High magnetic confinement increases plasma density and leads to higher fractional ionization of metal at the substrate. The N first coaxial coils and the M second coaxial coils may also be used to create the magnetic potential well in the PVD processing chamber. Creating the magnetic well in the processing chamber provides improved ion uniformity. As a result, the PVD system provides more uniform ion reflow capability across the substrate. The magnetic well also confines plasma on the substrate, which enhances the ion fraction and ion reflow capability and reduces damage to the substrate.

An example substrate for metal deposition is illustrated in FIG. 9A. The substrate may include a layer of dielectric with a pattern of vias and trenches lined with the barrier layer, such as Ta/TaNx or Ti/TiNx. The substrate is typically degassed prior to entering the PVD deposition chamber. Degassing may be performed prior to deposition of the barrier layer or immediately prior to metal fill. For example, degassing may include heating the substrate to a temperature of between about 200-400° C., at a pressure of between about 5-200 Torr in the presence of an inert gas such as helium or argon. In some examples, the substrate is transferred to the copper PVD chamber directly from a tantalum or titanium PVD chamber without exposure to ambient atmosphere.

After the substrate is positioned within the chamber, metal is deposited at 403 into the recessed features of the substrate at a first net deposition rate while metal is deposited simultaneously in the field at a lower rate or is not deposited in the field at all (e.g., diffusion barrier material is etched from the field).

In HDP metal fill, plasma is ignited and the substrate is exposed to highly ionized plasma characterized by at least about 30% fractional ionization of metal. In other examples, at least about 50% of metal is ionized in proximity to the substrate. In another example, at least about 80% of metal is ionized in proximity to the substrate. In still another example, at least about 99% of metal is ionized in proximity to the substrate. The plasma may also contain inert gas in neutral and ionic form. The presence of inert gas, however, is not required. In some examples, flow of inert gas is provided only when the plasma is ignited. The flow of gas is then stopped and plasma including mostly metal species is maintained. In other examples, the flow of inert gas may be provided during metal deposition, and the ratio of inert gas to metal species may reach unity. Inert gas flow during deposition may range from about 0 to about 100 sccm. In some examples, inert gas flow is about 0 to about 10 sccm, although other values may be used. Pressure within the deposition chamber may range from about 0.005 to about 5 mTorr. In other examples, a pressure from about 0.005 to about 0.5 mTorr is used.

An external RF bias may be optionally applied to the substrate. The bias will increase the negative DC bias on the substrate in the presence of plasma. The DC bias is measured relative to plasma potential. As RF substrate bias is increased, the energy of metal ions impacting the substrate is increased, thereby increasing the E rate (resputtering rate). The energy of metal ions may be controlled to ensure that net deposition occurs rather than net etching within the recesses.

In one example, the mean energy of ions impacting the substrate is kept below about 70 eV. In some examples, the substrate is kept at a potential of less than about 100 V relative to plasma potential. In one example, this is accomplished by not applying any external RF bias to substrate pedestal at all. In other examples an RF bias at a power level of up to about 300 W may be applied to the substrate having a diameter of 300 mm. (up to about 0.4 W/cm² power density). A negative DC bias is applied to the metal target during deposition. DC bias is applied to the target in some examples at a power level of about 20-100 kW. However, the target power level will depend on the size of a target and other factors.

In one specific example, copper is deposited in a processing chamber by maintaining the substrate at a substantially constant temperature of about 40° C. and exposing the substrate to plasma having high fractional ionization of copper. The deposition involves generating and maintaining highly confined plasma in the proximity of the target. This is accomplished by applying high current levels to electromagnetic coils and/or creating the magnetic potential well. Argon is supplied to the process chamber at a flow rate of about 2 sccm and pressure is maintained at about 0.05 mTorr. A negative DC bias is applied to copper target at a power level of about 70 kW.

After the recessed features are filled, the process may follow to an annealing operation at 405. Annealing is performed by heating the substrate to a temperature of between about 100-400° C. to change the copper microstructure from a small grain to a more desirable large grain formation. Copper lines with large grain microstructure are characterized by lower resistivity. PVD copper fill performed by exposing the substrate to highly ionized plasma as described above may perform self-annealing. For example, grains having lengths equal to trench height (e.g., 400-600 nm) and widths of about 70-150 nm may be obtained without annealing. Therefore, for HDP metal fill, the annealing operation is optional, and may be performed if the copper microstructure needs to be further improved.

After the optional anneal operation at 405, the substrate may be planarized, e.g., by a CMP operation in an operation 407. Planarization may be performed to remove copper overburden and/or the barrier layer from the field region. In other examples, when recessed features are only partially filled (e.g., 80% filled), planarization may be also used to remove the dielectric and to bring the dielectric level to the same level with the metal fill.

In other examples, CMP operations may not be required at all. The method can cleanly fill the trenches while removing all of the diffusion barrier layer from the field region and providing the planarized substrate (such as that in FIG. 9C) after PVD fill. After the partially fabricated structure, such as shown in FIG. 9C is formed, the process may proceed further as depicted in FIGS. 9D-9F.

### Atomic Layer Profiling (ALP) Metal Fill

In another approach, the recessed features are filled by PVD using atomic layer profiling (ALP) systems and methods to fill relatively narrow features and high aspect ratios. The ALP systems and methods overcome the problem of overhang formation and pinch-off by performing a plurality of cycles each including a net deposition operation and a net etch operation. As the cycles are repeated, the deposition and etch operations alternate. During the deposition operation, the metal flux is directed from the PVD target onto the substrate. During resputtering, the metal flux is primarily directed from the bottom of the recessed feature onto the sidewalls of the recessed feature (although a small portion of the flux may be derived from the target or the field region).

As a result, sidewalls of recessed features are exposed to alternating metal fluxes from substantially opposite directions, which reduces the overhang. Further, the etching operations, at least in some ALP cycles, will etch overhang material. By adjusting the durations of depositing and etching operations, and by adjusting plasma conditions used in these operations, partial or complete metal fill of vias and trenches is achieved.

All of the operations of ALP metal fill can be performed in one PVD chamber using a depositing plasma under one set of conditions for the depositing operation of the ALP cycle and using an etching (resputtering) plasma under a different set of conditions during the etching operation of the cycle. As a result, metal fill can be performed by modulating parameters, such as power levels applied to the target and substrate pedestal, without any changes to PVD hardware, or substrate transfer.

Further, it is noted that ALP metal fill can be performed at a substantially constant substrate temperature. For example, the temperature at the substrate pedestal, in some examples, does not fluctuate more than about 25° C. throughout the entire ALP process. In some examples, the substrate is maintained at a temperature of between about 25-50° C. during metal fill.

The ALP metal fill need not necessarily be performed exclusively in the PVD chamber. In some examples, at least some of net etching operations of the ALP metal fill are performed in a process chamber not having a metal target. For example, at least some of the etching operations may be performed in plasma pre-clean chamber. The pre-clean process chamber is configured for generation of plasma, (e.g., inductively coupled plasma) to produce energetic inert gas ions that can be used to resputter (etch) material from the substrate. Notably, in this configuration there is no metal flux derived from the target, because the pre-clean chamber does not contain a target.

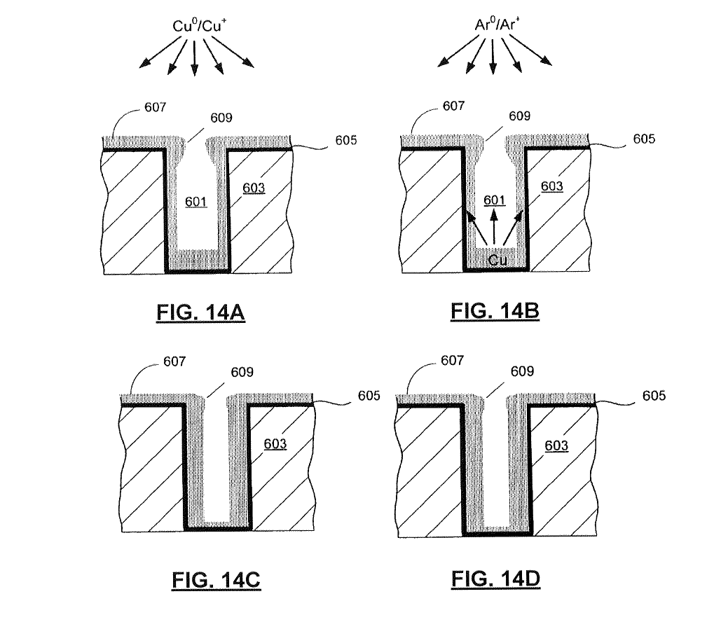

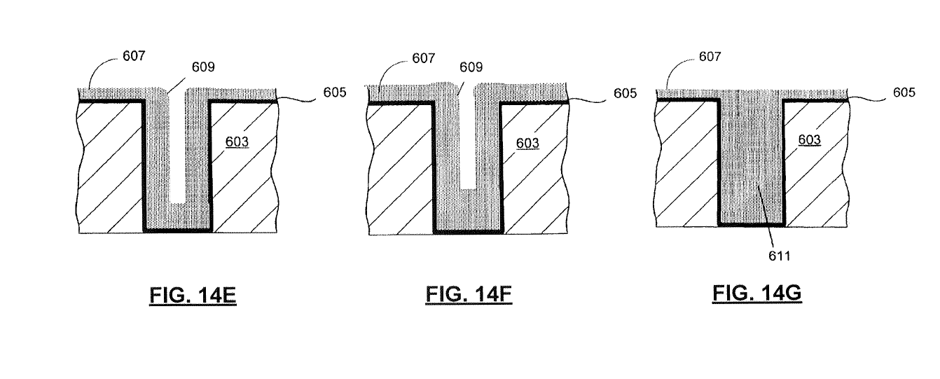

One example of the ALP method will now be illustrated with the reference to the process flow diagram shown in FIG. 13. Schematic cross-sectional depictions of partially fabricated structures obtained during ALP metal fill are shown in FIGS. 14A-14G.

In FIG. 13, the process starts at 501 by arranging a substrate with exposed recessed features in plasma PVD chamber. An example of such device is shown in FIG. 9A.

The processing chamber may include a three-dimensional target (e.g., an HCM), a planar magnetron or other magnetron may be used. The processing chamber may be capable of producing a depositing and an etching (resputtering) plasma, and may be configured for rapid switching between the depositing and the resputtering modes. The N first coaxial coils and the M second coaxial coils may be used to create the magnetic potential well in the PVD processing chamber. Alternatively, as it was described above, the depositing operations may be performed in a PVD chamber, while etching operations may be performed in a separate plasma pre-clean chamber. The substrate may be transferred between these two chambers without being exposed to an ambient atmosphere.

In the next operation 503, a plurality of ALP cycles are performed to partially or completely fill the recessed features with the metal. Each of the ALP cycles includes a net depositing operation and a net etching operation. Net etching and net deposition are typically measured on the field region. It is also preferable that net etching and net deposition occur at the recessed feature bottom. At least some of the etching operations of the profiling cycles will resputter metal from the bottom of the feature onto feature sidewalls. As these resputtering operations are repeated, the recessed feature is filled from the sidewalls to the center.

After the recessed feature is filled, the structure is annealed in operation 505, to improve the metal microstructure. Subsequently, in operation 507, undesired material (e.g., copper overburden and diffusion barrier material) is removed from the field by CMP. The planarized structure, such as structure shown in FIG. 9C is obtained as a result. The Damascene process may follow further, as depicted in FIGS. 9D-9F.

An ALP copper fill of a trench will be now illustrated with reference to structures shown in FIGS. 14A-14G. While a large number of ALP cycles may be used to fill a recessed feature, metal fill with only 3 ALP cycles will be described. A layer of copper is deposited on the substrate surface. In one example this is done by sputtering copper from the PVD target in plasma PVD apparatus. The plasma can include metal (in both ionized and neutral form) as well as inert gas ions. The plasma parameters are adjusted such that the E/D ratio is less than 1 both on the field and on the bottom of the trench. Therefore, copper is deposited both in the field and on the trench bottom. Sidewalls may also be covered in this operation. However, sidewall coverage may be thin and discontinuous.

In FIG. 14A, a trench 601 is formed in a dielectric layer 603 that is lined with a barrier layer 605. A flux of ionized and neutral copper is directed onto the substrate from the target to deposit a layer of copper 607. In this example, high fractional ionization of metal is not required, and copper may be deposited under conventional PVD conditions, e.g., predominantly by neutral copper atoms. As is typical for conventional PVD fill, overhangs 609 start to form. The first depositing operation, however, is typically relatively short and does not allow build-up of substantial overhangs. The first depositing operation provides copper coverage at the bottom of the trench, which will serve as a source of copper flux in the resputtering operation that follows.

After copper has been deposited onto the trench bottom to a certain thickness, a resputtering operation is performed. During resputtering, energetic ions (for example, inert gas ions, such as argon ions) impinge onto the exposed copper layer, and etch copper from both the trench bottom and the field region. The copper metal etched from the trench bottom is redistributed from the trench bottom onto the trench sidewalls, as shown in FIG. 14B. It can be seen that copper flux during resputtering is directed onto the sidewalls from below. Copper flux directed from the target is minimized during the resputtering operation. During resputter, the plasma need not necessarily be composed exclusively of gas species, and a certain fraction of metal species sputtered from the target may be present when the resputtering process is performed in a PVD chamber. In some examples, the amount of metal sputtered from the target is minimized by applying lower power to the target as compared to the target power used in deposition.

In some examples, E/D ratios (as measured in the field region) of greater than about 1.5 (or in some examples, greater than about 3) are used during resputtering operations. In some examples, the net etching operation removes copper from the trench bottom at an etch rate of at least about 3 Angstroms/second. In some examples, a net depositing operation of an ALP cycle deposits between about 50-600 Angstroms of copper onto the field region, while the subsequent etching operation etches at least about 40% of the deposited layer thickness (as measured in the field). In some examples, the net etching operation of an ALP cycle removes between about 40-100% of copper layer thickness as measured in the field region.

As can be seen in FIG. 14C, resputtering increases copper layer thickness on trench sidewalls while reducing copper thickness both on the field region and on the trench bottom. Overhangs 609 protrude to a lesser extent after resputtering has been performed. Overhangs are reduced in part because the sidewalls are exposed to copper flux from different directions, which results in increase of sidewall coverage and subsequent overhang decrease. In addition, the resputtering operation may partially etch copper from the overhangs (overhang clipping) to effectively increase the feature opening. The resputtering operation is controlled such that no overetching at the trench bottom is occurring. While in some examples it may be acceptable to etch all copper deposited at the trench bottom, care should be taken to preserve the barrier layer at the bottom of the trench, particularly if the trench resides over a layer of dielectric. In vias residing exclusively over underlying copper lines (landed vias) overetching into diffusion barrier or into underlying copper may be acceptable in some examples.

After the resputtering operation has been performed, a subsequent deposition operation follows and forms the substrate shown in FIG. 14D. The thickness of the copper layer at the trench bottom and on the field is increased. Next, an etching (resputtering) operation is performed to create the substrate shown in FIG. 14E, where the thickness of copper layer on the sidewalls is further increased, and the overhangs are reduced. Next, deposition operation follows to form a structure shown in FIG. 14F, where the coverage at the trench bottom and in the field is increased. Afterwards, another etching operation is performed to redistribute material from the trench bottom to the sidewalls, followed by a deposition operation to fill the trench and provide the substrate shown in FIG. 14G.

In general, an ALP cycle may start either with a depositing (Dep) or an etching (Etch) operation. It is understood that ALP metal fill process sequence starts by depositing metal at the trench bottom. This first depositing operation may be considered a separate operation or a part of the first ALP cycle. For example, the sequence of operations depicted in FIGS. 14A-14G can be presented as Dep/Etch/Dep/Etch/Dep/Etch/Dep or as Dep/Cycle1/Cycle2/Cycle3 or as Cycle1/Cycle2/Cycle3/Dep. Generally, the ALP metal fill process may end with either a depositing or an etching operation.

Depositing and etching operations for different ALP cycles may be carried out under the same or different conditions. It is advantageous that by varying parameters in ALP cycles (such as power levels applied to the target and substrate pedestal, magnetic confinement, pressure, durations of the depositing and etching operations, etc.), the ALP metal fill process may be optimized to fill the recessed features while minimizing overhang formation and pinch-off. In some examples, the deposition conditions in the depositing operation of the first ALP cycle are different than deposition conditions employed in subsequent ALP cycles, which may in turn be different than deposition conditions of prior ALP cycles.

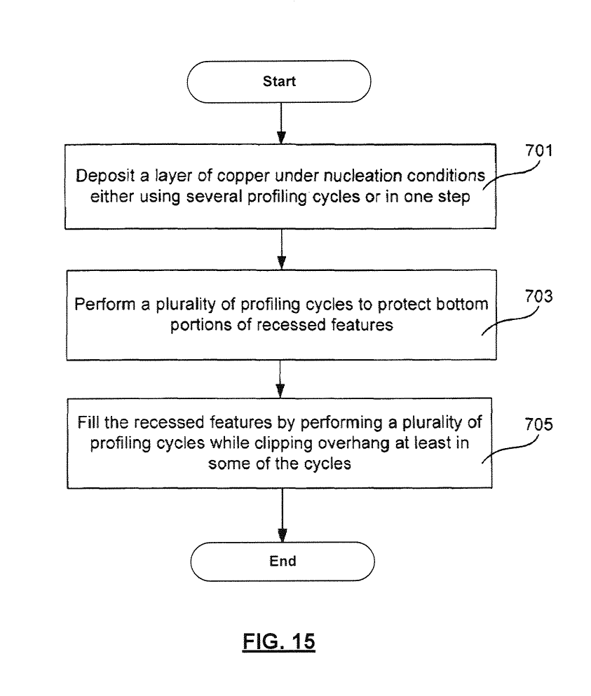

In FIG. 15, different conditions are used in different ALP cycles to achieve optimal fill. In this example, the process starts in operation 701 to deposit a layer of copper under nucleation deposition conditions. This operation may be viewed as a separate operation or as a first depositing operation of a first ALP cycle.

Nucleation is performed using plasma characterized by a relatively high fractional ionization of copper, e.g., with plasma having fractional copper ionization of greater than about 30%. In one example, the nucleation plasma includes about 80% of inert gas species (ions or neutral atoms) and about 20% of copper species with the fractional copper ionization of about 50%. In some examples nucleation is performed by sputtering copper under following conditions: substrate temperature of between about −50° C. to 150° C., chamber pressure of about 0.005-0.6 mTorr, RF power applied to substrate pedestal of between about 0-300 W, DC target power of between about 20-100 kW and an argon flow rate of between about 0-10 sccm.

In a specific example, nucleation is performed by sputtering copper onto the substrate under the following conditions: substrate temperature about 50° C., pressure of about 0.05 mTorr, no external RF power applied to substrate pedestal, DC target power of about 70 kW and an argon flow rate of about 2 sccm.

After the nucleation layer of copper has been deposited, the deposition conditions in subsequent ALP cycles may use plasma with a lower fractional ionization of copper. This can be done by lowering the magnetic confinement of plasma in subsequent depositing operations, and by using a higher argon flow rate. For example, magnetic field strength at the target may be lowered by at least about 10%. In some examples, the magnetic field strength is lowered by at least about 25% (as compared to nucleation deposition conditions).

After the copper nucleation layer is formed, a plurality of profiling cycles is performed at 703 to protect bottom portions of recessed features. The objective of these cycles is to build a layer of copper at the trench bottom to protect the trench bottom from overetching, which may inadvertently occur during aggressive resputtering. In protective ALP cycles, an etching operation may remove less than about 70% of the copper layer thickness deposited in the prior depositing operation. For example, no more than 50% of the copper layer thickness may be removed by the etching operation, as measured in the field. In a specific example, each depositing operation of a protective ALP cycle deposits about 100 Angstroms of copper on the field, while each etching operation removes about 50 Angstroms of copper from the field. Therefore, each ALP cycle deposits a net of 50 Angstroms of copper on the field. The thickness of the copper layer deposited at the trench bottom is typically between about 10-90% of the thickness of the copper layer deposited on the field depending on trench aspect ratio. In some examples, between about 1-10 protective ALP cycles are performed until the trench bottom is sufficiently covered. In subsequent ALP cycles, more aggressive etch-back operations may be used. For example, in subsequent ALP cycles at least about 70% of the deposited layer thickness (as measured in the field) is removed during etch-back in each cycle.

As shown in operation 705 of FIG. 15, after the protective ALP cycles have been performed, ALP cycles are used to complete the filling of the trench. For at least some of the etching operations in these ALP cycles, the conditions may be adjusted such that etching reduces (clips) the overhangs.

In one example, the trench is filled by performing the following sequence. First, one nucleation ALP cycle, starting with a depositing operation is performed. The depositing operation of this cycle deposits 100 Angstroms of copper under nucleation conditions. The following etching operation etches 50 Angstroms of deposited copper layer, as measured in the field. Next, six protective ALP cycles are performed. Each cycle starts with a depositing operation which deposits 100 Angstroms of copper under general deposition conditions and follows with an etching operation, which 50 Angstroms of deposited copper. Next, fifty filling ALP cycles are performed. In each filling ALP cycle, the depositing operation deposits 100 Angstroms of copper under general deposition conditions and the following etching operation etches 70 Angstroms of copper.

In general, a variety of PVD conditions are suitable for PVD deposition and PVD etch operations. For the net deposition process the DC power can range from about 5 W/(cm² target) to 25 W/(cm² target), and, for the RF power, from about 0 W/(cm² substrate) to 0.5 W/(cm² substrate). For the etchback (resputter) operation, the combination of DC power applied to the target and RE power applied to the substrate may ensure the net material removal from the substrate. For example, for HCM modules having target areas of between about 1000-6000 cm², DC power should be in the range from 1 kW to 10 kW or as low as 0 for the pure etching. The range will depends on the target area, and can be different for smaller or bigger targets especially if the method is used with the different source/target design. The RF power may be between about 100 W to 3000 W for a typical substrate (e.g., a 300 mm substrate). This range depends on the substrate area and can be much greater for applications that deal with larger substrates. In terms of power density (independent of the target area or substrate area), examples of suitable DC power ranges for the sputter etch operation are range from about 0 W/(cm² target) to 5 W/(cm² target) and for the RF power, from about 0.1 W/(cm² substrate) to 5 W/(cm² substrate).

In some examples, resputtering is performed in a low-energy regime. This type of resputtering utilizes relatively low-energy ions as the resputtering species and makes use of high density plasma. Under these conditions, the resputtering plasma has a density of at least about 10¹⁰ electrons/cm³ proximate to the substrate, and a mean ion energy of about 100-700 eV for the ions impinging onto the substrate. Argon-rich plasma may be used for resputtering. For example, the plasma may contain at least about 80%, (or in some examples, at least about 90%) of inert gas species. In one example the plasma contains about 95% of Ar+ ions and about 5% of Cu+ ions. High density plasma low energy resputter can be performed using relatively low RF bias applied to the substrate to decrease ion energy. The plasma density in the proximity of the substrate can be increased with the use of an ion extractor, which will be described in detail below.

Suitable conditions for high plasma density low energy resputtering include: a substrate temperature in the range of between about −50° C. to 100° C., a pressure of between about 0.5-5 mTorr, RF power applied to the substrate pedestal of between about 200-1000 W (in some example, less than about 500 W), DC target power of about 0.5-10 kW, and an argon flow rate of between about 10-200 sccm.

Typically, in an ALP cycle, switching from a depositing operation to an etching operation is performed by decreasing the DC power applied to the target to reduce the copper flux from the target. In some examples, Argon-rich plasma with at least about 9:1 argon/copper ratio is preferred during etch-back. In some examples, the DC power applied to the target is reduced from about 50-70 kW during depositing operation to about 1-3 kW during resputter. Further, in some examples, resputtering is performed using a higher RF substrate bias. For example, deposition may be performed without applying an external bias to the substrate. When switching from deposition to etching, the RF bias may be increased, e.g., to about 600 W. In addition, in many examples, argon flow rate is increased while switching from deposition to resputter to provide a more argon-rich plasma.

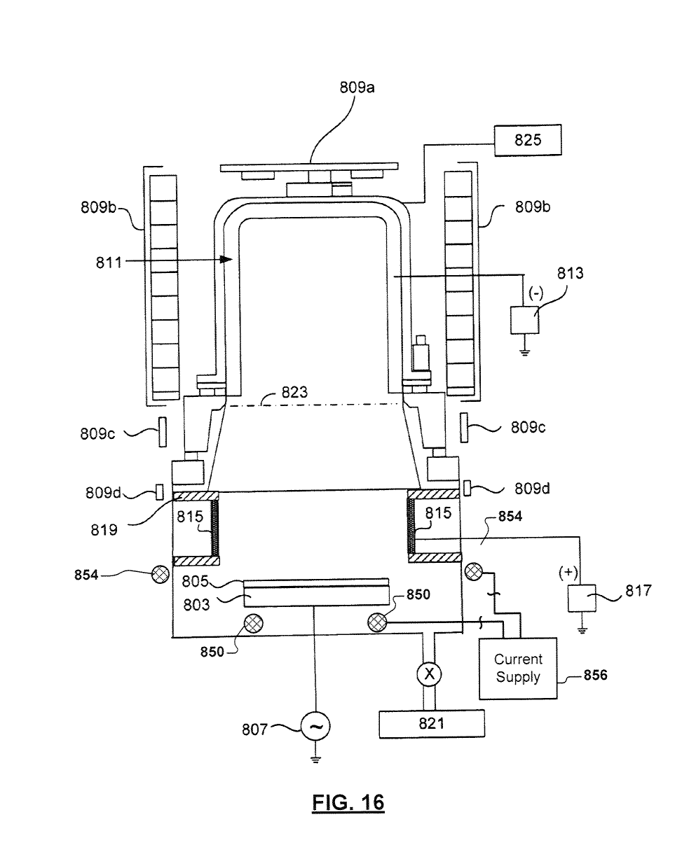

Referring now to FIG. 16, an example of a processing chamber 800 includes a pedestal 803, on which a substrate 805 resides. An RF power supply 807 is connected to the pedestal 803 to provide an RF bias during deposition and/or resputtering. In some examples, deposition and/or resputtering may be performed without applying an RF bias to the substrate. The pedestal 803 may also provide temperature control for the substrate 805. In some examples, the temperature at the substrate pedestal can range from about −50° C. to 600° C. In other examples, the temperature of the substrate is between about 0 and 150° C.

Resputtering typically requires application of the RF bias to increase the energy of ions impinging on the substrate. In some examples, an RF bias power of between about 100 W to 3 kW is used for resputtering for a 300 mm substrate. Energy of impacting ions is primarily controlled by the bias at the substrate, with lower bias resulting in lower ion energy.

The processing chamber 800 may further include a rotating magnet 809a and one or more electromagnets 809b-809d. A target 811 may be an HCM target, a planar target or another suitable target that is made of a material to be deposited. The target is electrically connected to the DC power supply 813. The density of plasma can be controlled by controlling magnetic confinement of plasma near the target 811 and in the vicinity of the substrate.

In some examples, highly magnetically confined plasma may be generated by applying a magnetic field in the target region. In one example, HOP metal fill involves passing high currents through electromagnetic coils 809b. In a specific example current is passed through at least some coils to generate a magnetic field of at least about 0.1 Tesla in the vicinity of the target, and to form plasma having a density of at least about 10¹³ electrons/cm³ within the target region. The N first coaxial coils and the M second coaxial coils may be used to create a magnetic potential well in the PVD processing chamber, as will be described below. Creating the magnetic well in the processing chamber provides improved ion uniformity. As a result, the PVD system provides more uniform ion reflow capability across the substrate. The magnetic well also confines plasma on the substrate, which enhances the ion fraction and ion reflow capability and reduces damage to the substrate.

One or more shields may be positioned near sidewalls of the processing chamber 800 to protect the sidewalls from the sputtered material. For example, the shield 815 is arranged in the processing chamber 800. The shield 815 may be positively biased and serve as an “ion extractor” to increase plasma density in the proximity of the substrate by transferring ions from a high plasma density region to the substrate region. The shield 815 is connected to a DC power supply 817. In some examples, a bias between about 30V to 300 V is provided by the DC power supply 817. In other examples, a bias between about 100 V to 150 V is applied to the shield 815.

The shield 815 may be electrically isolated from the process chamber sidewalls by ceramic rings 819. For example, the shield 815 may include an aluminum member having a hollow cylindrical shape. The shield may be located a predetermined distance (such as about 8 cm) above the pedestal 803 and below the target 811 (such as about 16 cm). Note, that since the shield 815 is positively biased during operation, material from the shield is not substantially sputtered onto the substrate. Therefore, the shield 815 can be made of a variety of conductive materials, which may be different than the material being deposited or resputtered onto the substrate. For example, an aluminum shield can be used during copper resputter. The ALP metal fill and high density metal fill may also be performed without the use of the shield 815.

An inert gas, such as argon, may be introduced through a gas inlet (not shown) into the process chamber from the sides below the shield 815. A pump 821 may evacuate or partially evacuate the process chamber 800 as needed. The control of pressure in the process chamber can be achieved by using a combination of gas flow rate adjustments and pumping speed adjustments (for example, via a throttle valve or a baffle plate). Typically the pressure ranges between about 0.001 mTorr to about 100 mTorr during the deposition and resputtering processes.

According to the present disclosure, a magnetic field (potential) well is created in the vicinity of the substrate using N first and M second coaxial coils 850 and 854, respectively. The magnetic field well is defined by a region that has an approximately zero magnetic field surrounded by a region having a very strong magnetic field. Charged species can move fairly freely inside the magnetic field well but cannot easily escape. Creating the magnetic field well with an appropriate diameter (approximately equal to a diameter of the substrate) near the substrate allows the ions to distribute freely over the substrate while being confined to the volume spanned by the substrate diameter.

To create the magnetic field well, N first coaxial coils 850 with N first coaxial coil diameters are arranged below the substrate in the substrate region, where N is an integer greater than zero. M second coaxial coils 854 with M second coaxial coil diameters are arranged above the substrate in the target region, where M is an integer greater than zero. The N first coaxial coil diameters can be the same or different. The M second coaxial coil diameters can be the same or different.

In a first example, the diameters of the N first coaxial coils 850 are less than the diameters of the M second coaxial coils 854. For example only, diameters of the N first coaxial coils 850 may be approximately 8-12 inches and diameters of the M second coaxial coils 854 may be 16-30 inches, although other dimensions may be used. In another example, the N first coaxial coils 850 may have a diameter approximately equal to a diameter of the substrate and the M second coaxial coils 854 may have a diameter that is T times the diameter of the substrate 16, where T is greater than or equal to 1.

A current supply 856 supplies N currents that flow in a first direction in each of the N first coaxial coils 850, respectively. The current supply 856 supplies M currents that flow in a second direction in each of the M second coaxial coils 854, respectively. The first direction is opposite to the second direction. In some examples, the sum of the magnetic fields generated by the N first coaxial coils is opposite to the sum of the magnetic fields generated by the M second coaxial coils. In other examples, when N or M are greater than one, the additional coils can be arranged radially outside of each other in the same plane or axially on top of each other.

When the N currents flow in opposite directions in the N first coaxial coils 850 with respect to the M currents flowing in the M second coaxial coils 854, the magnetic fields cancel inside the N first coaxial coil diameters and add outside of the N first coaxial coil diameters. With appropriate diameters and current magnitudes, the magnetic field well can be created. The well radius can be adjusted by varying current magnitudes and the coaxial coil diameters.

Magnitudes of the M currents may be adjusted relative to magnitudes of the N currents. For example only, a smallest one of the M currents may be approximately two times a greatest one of the N currents. In addition, the N currents supplied to the N first coaxial coils may have the same or different current values. Likewise, the M currents supplied to the M second coaxial coils may have the same or different current values. For example only, the first and second coaxial coils 850, 854 may be spaced approximately the same distance below and above the substrate, respectively. In one example, the N first coaxial coils 850 and the M second coaxial coils 854 are arranged 0-6 inches below and above the substrate, respectively.

The creation of the magnetic field well in the vicinity the substrate results in a high density uniform plasma over the surface of the substrate, which leads to high quality uniform film deposition. The N first coaxial coils 850 below the substrate and the M second coaxial coils 854 above the substrate run opposite currents with respect to each other. By modulating the strength and dimension of the magnetic field well, uniform deposition and resputtering profiles can be achieved.

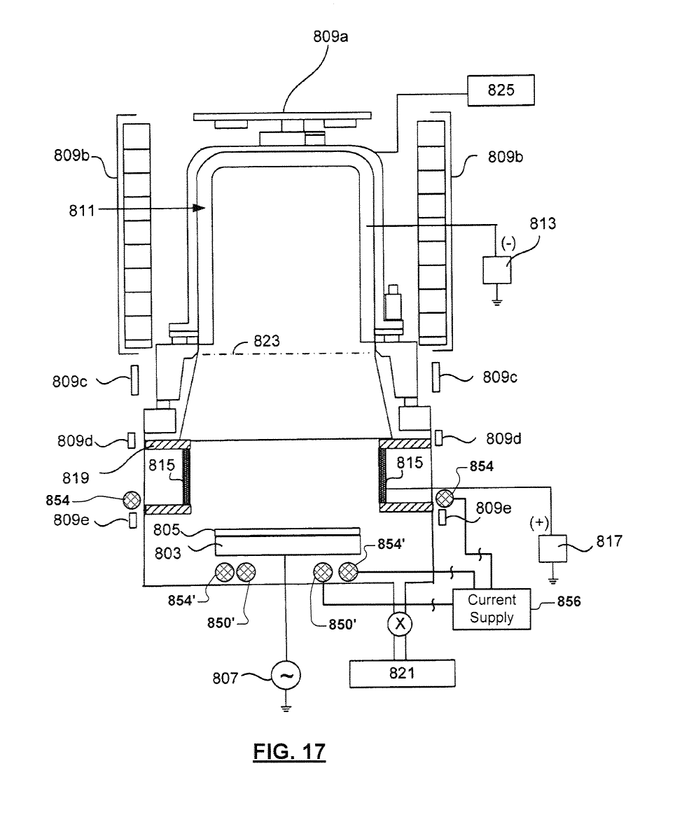

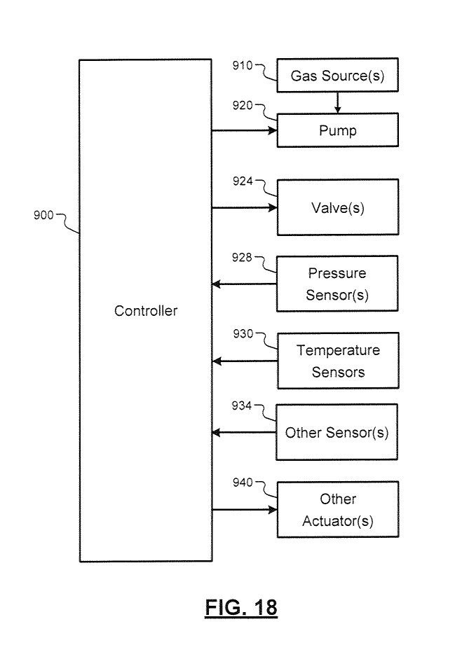

Referring now to FIG. 17, a PVD system 800′ is shown. As can be appreciated, N first coaxial coils 850′ and M second coaxial coils 854 and 854′ can be arranged in other locations relative to the substrate 16. For example in FIG. 17, the N first coaxial coils 850′ and one or more of the M second coaxial coils 854′ can be located in one or more planes below the substrate. If used, the remaining ones of the M second coaxial coils 854 may be located in a plane above the substrate as shown in FIG. 16. In other examples, all of the M second coaxial coils are arranged below the substrate.

When the N currents flow in opposite directions in the N first coaxial coils 850′ with respect to the M currents flowing in the M second coaxial coils 854 and 854′, the magnetic fields cancel inside the coil diameters and add outside of the coil diameters. With appropriate diameters and current magnitudes, the magnetic field well can be created. The radius of the magnetic field well can be adjusted by varying current magnitudes, coil position, and the first and second coaxial coil diameters.

For example, the N first and some of the M second coaxial coils 850′ and 854′ can be arranged approximately 0″-6″ below the substrate. In one example, the N first and some of the M second coaxial coils 850′ and 854′ can be arranged approximately 1″ below the substrate, the inner and outer diameters of the N first coaxial coils 850′ can be 12″/12.7″, respectively, and the inner and outer diameters of the M second coaxial coils 854′ can be 13.7″/14.7″, respectively, although other values may be used. As used herein, approximately refers to +/−0.25″. The remaining ones of the M second coaxial coils 854 may be arranged above the substrate as described above.

The N first coaxial coils 850′ and the M second coaxial coils 854′ run opposite currents with respect to each other. With the magnetic field generated by other coils or magnets, a magnetic potential well that is larger than the substrate size can be formed to facilitate plasma distribution.

Referring now to FIG. 19, a controller 900 may be provided to control the processes described above. In particular, the controller 900 may control one or more gas sources 910 via one or more pumps 920 and valves 924. The controller 900 may receive outputs of one or more pressure sensors 928 and/or temperature sensors 930 that are arranged in various locations inside and outside of the processing chamber. Still other sensors 934 and actuators 940 may be used.

The controller 900 may be provided with program instructions for implementing the above-described processes. The program instructions may monitor the sensors and control a variety of actuators and process parameters, such as power level, bias power level, pressure, gas flow, arm position, temperature, etc. based on the sensed values.

The apparatus/process described hereinabove may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility. Lithographic patterning of a film typically includes some or all of the following operations, each operation enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

The broad teachings of the disclosure can be implemented in a variety of forms. Therefore, while this disclosure includes particular examples, the true scope of the disclosure should not be so limited since other modifications will become apparent to the skilled practitioner upon a study of the drawings, the specification, and the following claims.

What is claimed is:

1. A method of operating a physical vapor deposition (PVD) system, comprising:
arranging N coaxial coils in a first plane parallel to a substrate-supporting surface of a pedestal in a chamber of a PVD system and below the pedestal;
arranging M coaxial coils adjacent to the pedestal, where N and M are integers greater than zero;
creating plasma in the chamber;
creating a magnetic field well above a substrate by supplying N currents to the N coaxial coils, respectively, and M currents to the M coaxial coils, respectively,
wherein the N currents flow in a first direction in the N coaxial coils and the M second currents flow in a second direction in the M coaxial coils that is opposite to the first direction; and
filling a recessed feature on a substrate arranged on the pedestal with a metal-containing material by PVD using at least one operation with high density plasma having a fractional ionization of metal greater than 30%.

2. The method of claim 1, wherein the fractional ionization of metal is greater than 50%.

3. The method of claim 1 further comprising:
depositing a layer of the metal-containing material on the substrate and coating at least a bottom portion of the recessed feature; and
performing a plurality of profiling cycles,
wherein each of the plurality of profiling cycles comprises a net etching operation removing a first portion of a material residing at the bottom of the recessed feature and a net deposition operation depositing a second portion of a material at the bottom of the recessed feature.

4. The method of claim 3, wherein:
the net etching operation comprises redistributing the metal-containing material from the bottom portion of the recessed feature to sidewalls of the recessed feature in at least some of the plurality of profiling cycles,
performing the plurality of profiling cycles fills the recessed feature with the metal-containing material, and
removing the first portion of a material residing at the bottom of the recessed feature comprises resputtering the material using high density plasma resputtering in at least some of the plurality of profiling cycles.

5. The method of claim 3, wherein:
a deposited portion of the material is greater than an etched portion of the material for at least one of the profiling cycles;
performing the plurality of profiling cycles achieves net material deposition at the bottom portion of the recessed feature; and
the net etching operation comprises resputtering the material from the bottom of the recessed feature using high density plasma resputtering in at least some of the plurality of profiling cycles.

6. The method of claim 3, wherein the net etching operation reduces overhang material residing at an opening of the recessed feature during at least some of the profiling cycles.

7. The method of claim 1, wherein the metal-containing material comprises copper.

8. The method of claim 3, wherein the substrate comprises a Damascene structure.

9. The method of claim 1, wherein the recessed feature has a width of less than about 300 nm.

10. The method of claim 1, wherein performing the plurality of profiling cycles comprises performing a first profiling cycle having a first net etching operation followed by a second profiling cycle having a second net etching operation, wherein the second net etching operation removes a larger fraction of deposited material than the first net etching operation.

11. The method of claim 3, wherein the net deposition operation comprises applying an RF bias to the substrate.

12. The method of claim 1, wherein arranging the M coaxial coils includes arranging the M coaxial coils in a second plane that is parallel to the surface of the pedestal and above the surface of the pedestal.

13. The method of claim 1, wherein arranging the M coaxial coils includes arranging the M coaxial coils in a second plane that is parallel to the surface of the pedestal and below the surface of the pedestal.

14. The method of claim 1, wherein arranging the M coaxial coils includes:
arranging at least some of the M coaxial coils in a second plane that is parallel to the surface of the pedestal and below the surface of the pedestal; and
arranging remaining ones of the M coaxial coils in a third plane that is parallel to the surface of the pedestal and above the surface of the pedestal.

15. The method of claim 1, wherein:
the magnetic field well is generally “U”-shaped and is centered on the substrate-supporting surface of the pedestal;
a magnetic null is located inside the magnetic field well; and
a strong magnetic field is located outside of the magnetic field well.

16. The method of claim 3, wherein:
at least one of the N coaxial coils has a first diameter, and
at least one of the M coaxial coils has a second diameter, wherein the second diameter is greater than the first diameter.

17. The method of claim 3, wherein the PVD system includes a hollow cathode magnetron (HCM) target.

18. A physical vapor deposition (PVD) system, comprising:
a chamber;
a target arranged in a target region of the chamber;
a pedestal having a surface for supporting a substrate and arranged in a substrate region of the chamber, wherein a transfer region is located between the target region and the substrate region;
N coaxial coils arranged in a first plane parallel to the surface of the pedestal and below the pedestal;
M coaxial coils, where N and M are integers greater than zero, wherein N currents flow in a first direction in the N coaxial coils, respectively, and M currents flow in a second direction in the M coaxial coils that is opposite to the first direction, respectively; and
a controller comprising program instructions for:
creating plasma in the chamber; and
filling a recessed feature on a substrate arranged on the pedestal with a metal-containing material by PVD using at least one operation with high density plasma having a fractional ionization of metal greater than 30%.

19. The PVD system of claim 18, wherein the fractional ionization of metal is greater than 50%.

20. The PVD system of claim 18, wherein the controller further comprises program instructions for:
depositing a layer of the metal-containing material on the substrate and coating at least a bottom portion of the recessed feature; and
performing a plurality of profiling cycles,
wherein each of the plurality of profiling cycles comprises a net etching operation removing a first portion of a material residing at the bottom of the recessed feature and a net deposition operation depositing a second portion of a material at the bottom of the recessed feature.

21. The PVD system of claim 20, wherein:
the net etching operation comprises redistributing the metal-containing material from the bottom portion of the recessed feature to sidewalls of the recessed feature in at least some of the plurality of profiling cycles,
performing the plurality of profiling cycles fills the recessed feature with the metal-containing material, and
removing the first portion of a material residing at the bottom of the recessed feature comprises resputtering the material using high density plasma resputtering in at least some of the plurality of profiling cycles.

22. The PVD system of claim 20, wherein:
a deposited portion of the material is greater than an etched portion of the material for at least one of the profiling cycles;
performing the plurality of profiling cycles achieves net material deposition at the bottom portion of the recessed feature; and
the net etching operation comprises resputtering the material from the bottom of the recessed feature using high density plasma resputtering in at least some of the plurality of profiling cycles.

23. The PVD system of claim 20, wherein the net etching operation reduces overhang material residing at an opening of the recessed feature during at least some of the profiling cycles.

24. The PVD system of claim 18, wherein the metal-containing material comprises copper.

25. The PVD system of claim 20, wherein the substrate comprises a Damascene structure.

26. The PVD system of claim 20, wherein the recessed feature has a width of less than about 300 nm.

27. The PVD system of claim 18, wherein the controller further comprises program instructions for performing the plurality of profiling cycles comprises:
performing a first profiling cycle having a first net etching operation followed by a second profiling cycle having a second net etching operation, wherein the second net etch operation removes a larger fraction of deposited material than the first net etch operation.

28. The PVD system of claim 20, wherein the net deposition operation comprises applying an RF bias to the substrate.

29. The PVD system of claim 18, wherein the M coaxial coils are arranged in a second plane that is parallel to the surface of the pedestal and above the surface of the pedestal.

30. The PVD system of claim 18, wherein the M coaxial coils are arranged in a second plane that is parallel to the surface of the pedestal and below the surface of the pedestal.

31. The PVD system of claim 18, wherein:
at least some of the M coaxial coils are arranged in a second plane that is parallel to the surface of the pedestal and below the surface of the pedestal; and
remaining ones of the M coaxial coils are arranged in a third plane that is parallel to the surface of the pedestal and above the surface of the pedestal.

32. The PVD system of claim 18, wherein:
the N coaxial coils and the M coaxial coils create a magnetic field well that is generally “U”-shaped and is centered on a substrate-supporting surface of the pedestal;
a magnetic null is located inside the magnetic field well; and
a strong magnetic field is located outside of the magnetic field well.

33. The PVD system of claim 20, wherein:
at least one of the N coaxial coils has a first diameter, and
at least one of the M coaxial coils has a second diameter, wherein the second diameter is greater than the first diameter.

34. The PVD system of claim 20, wherein the target includes a hollow cathode magnetron (HCM) target.
